(19) United States
(12) Patent Application Publication
(10) Pub. No.: US 2022/0131055 A1
(43) Pub. Date: Apr. 28, 2022

(54) LIGHT SOURCE DEVICE, DISPLAY DEVICE AND MANUFACTURING METHOD OF LIGHT SOURCE DEVICE

(71) Applicant: Sharp Fukuyama Semiconductor Co., Ltd., Fukuyama City (JP)

(72) Inventors: MASUMI MAEGAWA, Fukuyama City (JP); HIROAKI ONUMA, Fukuyama City (JP); Narakazu SHIMOMURA, Fukuyama City (JP); Yuhsuke FUJITA, Fukuyama City (JP); Kyohei MIKAMI, Fukuyama City (JP)

(21) Appl. No.: 17/511,508

(22) Filed: Oct. 26, 2021

(30) Foreign Application Priority Data
Oct. 27, 2020 (JP) 2020-179671

(51) Int. Cl. H01L 33/58; H01L 27/15; H01L 33/00; H01L 33/50; H01L 33/60; H01L 33/62

(52) U.S. Cl. CPC H01L 33/58; H01L 27/156; H01L 33/0075; H01L 2933/0066; H01L 33/60; H01L 33/62; H01L 2933/0058; H01L 33/50

(57) ABSTRACT

A manufacturing method includes: a step of forming a light-emitting element layer by forming a semiconductor layer, a light-emitting layer, and a semiconductor layer in this order from a side with a first substrate on a surface, of the first substrate, on one side; a step of forming a separation trench in the light-emitting element layer to form a plurality of island shape light-emitting element layers; a step of forming a light shielding layer made of a material different from a material of the light-emitting element layer, in the separation trench; and a step of forming a plurality of light-emitting elements each including a corresponding one of the plurality of island shape light-emitting element layers having a height less than a height of the light shielding layer by etching a portion of the semiconductor layers of each of the plurality of island shape light-emitting element layers.

### CROSS-REFERENCE TO RELATED APPLICATION

The present application claims priority from Japanese Application JP2020-179671, the content of which is hereby incorporated by reference into this application.

### BACKGROUND OF THE INVENTION

### 1. Field of the Invention

The present disclosure relates to a light source device, a display device, and a manufacturing method of a light source device.

### 2. Description of the Related Art

In recent years, display devices and light source devices provided with, for example, micro LEDs as light-emitting elements have been proposed. Such a micro LED has high usage efficiency of light compared with other micro displays, can be expected to achieve high luminance, and also has low power consumption. Hence, the micro LED is expected to be applied in a variety of fields.

WO 2019/092893 discloses a configuration in which a light shielding layer is provided between adjacent micro LEDs in order to efficiently extract light emitted from each micro LED. After a plurality of micro LEDs are provided on a base substrate, the light shielding layer made of a resist material is formed on the entire surface of the base substrate to cover each of the plurality of micro LEDs. The light shielding layer made of the resist material formed on the entire surface on the base substrate is patterned by photolithographic method to remove portions, of the light shielding layer, on the plurality of respective micro LEDs. Accordingly, a configuration in which the light shielding layer is provided between adjacent micro LEDs is realized.

### SUMMARY OF THE INVENTION

The light shielding layer made of the resist material, which is described in WO2019/092893 described above, needs to be formed with a relatively uniform film thickness on the entire surface of the base substrate. However, in order to increase the height (thickness) of the light shielding layer, the viscosity of the resist material needs to be increased, and when the resist material having the high viscosity is spin coated, a uniform film cannot be formed due to the spin coating properties, and the height (thickness) of the light shielding layer to be formed is limited. Furthermore, the height (thickness) or the like of the light shielding layer that can be formed is limited due to a limit of the achievable aspect ratio (ratio of the height (thickness) and the width of the light shielding layer) and positional accuracy in the photolithographic method. For such reasons, the configuration described in WO2019/092893 has a problem in that it is difficult to provide a light shielding layer having a sufficient height.

An aspect of the present disclosure has been made in view of the problems described above, and an object of the present disclosure is to provide a light source device provided with a light shielding layer having a sufficient height between a plurality of light-emitting elements and a display device, and a manufacturing method of the light source device.

In order to solve the problems described above, a manufacturing method of a light source device according to an aspect of the present disclosure includes:

a step of forming a light-emitting element layer by forming a first semiconductor layer, a light-emitting layer, and a second semiconductor layer in this order from a side with a substrate on a surface, of the substrate, on one side;
a step of forming a separation trench in the light-emitting element layer to form a plurality of island shape light-emitting element layers;
a step of forming a light shielding layer made of a material different from a material of the light-emitting element layer, in at least the separation trench; and
a step of forming a plurality of light-emitting elements each including a corresponding one of the plurality of island shape light-emitting element layers having a height less than a height of the light shielding layer by etching one of the first semiconductor layer or the second semiconductor layer of each of the plurality of island shape light-emitting element layers after the step of forming the light shielding layer in the separation trench.

In order to solve the problems described above, a light source device according to an aspect of the present disclosure includes:

a base substrate provided with a drive circuit or a wiring line;
a plurality of light-emitting elements each including an electrode electrically connected to the drive circuit or the wiring line, a first semiconductor layer, a light-emitting layer, a second semiconductor layer in this order from a side with the base substrate on a surface of the base substrate;
a separation trench formed in at least the first semiconductor layer, the light-emitting layer, and the second semiconductor layer between the plurality of light-emitting elements; and
a light shielding layer provided in the separation trench to be higher than heights of the plurality of light-emitting elements.

A display device according to an aspect of the present disclosure includes: the light source device described above, wherein

the plurality of light-emitting elements includes a first light-emitting element, a second light-emitting element, and a third light-emitting element disposed adjacent to each other, one pixel includes a first subpixel, a second subpixel, and a third subpixel,
the first subpixel includes the first light-emitting element,
the second subpixel includes the second light-emitting element,
the third subpixel includes the third light-emitting element, and
the first subpixel, the second subpixel, and the third subpixel are subpixels configured to emit light beams having colors different from each other.

A manufacturing method of a light source device according to an aspect of the present disclosure includes:

a step of forming a light-emitting element layer by forming a first semiconductor layer, a light-emitting layer, and a second semiconductor layer in this order from a side with a substrate on a surface, of the substrate, on one side;
a step of forming a plurality of island shape light-emitting element layers by forming a separation trench in the light-emitting element layer;
a step of forming a first light shielding layer made of a material different from a material of the light-emitting element layer at least in the separation trench;
a step of etching the first semiconductor layer of each of the plurality of island shape light-emitting element layers; and
a step of forming a protruding pattern serving as a second light shielding layer on the first semiconductor layer.

A light source device according to an aspect of the present disclosure includes:

a base substrate provided with a drive circuit or a wiring line;
a plurality of light-emitting elements including an electrode electrically connected to the drive circuit or the wiring line, a first semiconductor layer, a light-emitting layer, and a second semiconductor layer in this order from a side with the base substrate on a surface of the base substrate; and
a separation trench formed in at least a portion of the first semiconductor layer, the light-emitting layer, and the second semiconductor layer between the plurality of light-emitting elements, wherein
the separation trench is filled with a first light shielding layer, and
a second light shielding layer including a protruding pattern provided on a surface, of the first semiconductor layer, on a light-emitting side is included between the plurality of light-emitting elements.

An aspect of the present disclosure can provide a light source device provided with a light shielding layer having a sufficient height between a plurality of light-emitting elements, a display device, and a manufacturing method of a light source device.

### BRIEF DESCRIPTION OF DRAWINGS

FIG. 1 is a diagram illustrating a manufacturing method of a light source device according to a first embodiment.

FIG. 2 is a diagram illustrating an overall configuration of the light source device according to the first embodiment.

FIG. 3 is a plan view in a case where the light source device according to the first embodiment illustrated in FIG. 2 is provided with a second electrode.

FIG. 4 is a diagram for describing a reason why light extraction efficiency is improved in the light source device according to the first embodiment.

FIG. 5 is a diagram illustrating another example of the case where the light source device according to the first embodiment is provided with a second electrode.

FIG. 6 is a plan view in a case where the light source device according to the first embodiment illustrated in FIG. 5 is provided with the second electrode.

FIG. 7 is a diagram illustrating an example in a case where the light source device according to the first embodiment is a monochromatic light-emitting light source device.

FIG. 8 is a diagram illustrating an example of a display device provided with the light source device according to the first embodiment.

FIG. 9 is a diagram illustrating a manufacturing method of a light source device according to a second embodiment.

FIG. 10 is a diagram illustrating another manufacturing method of the light source device according to the second embodiment.

FIG. 11 is a diagram illustrating an example in a case where the light source device according to the second embodiment is provided with a second electrode.

FIG. 12 is a diagram illustrating a manufacturing method of a light source device according to a third embodiment.

FIG. 13 is a diagram illustrating an overall configuration of the light source device according to the third embodiment.

FIG. 14 is a diagram illustrating an overall configuration of a light source device according to a fourth embodiment.

FIG. 15 is a diagram illustrating an overall configuration of a light source device according to a fifth embodiment.

FIG. 16 is a diagram illustrating an example in a case where a light source device according to a sixth embodiment is provided with a second semiconductor layer as a second electrode.

FIG. 17 is a plan view of the light source device according to the sixth embodiment illustrated in FIG. 16.

FIG. 18 is a diagram illustrating an overall configuration of a light source device of a modification example of the sixth embodiment.

FIG. 19 is a diagram illustrating a schematic cross-sectional view of a light source device according to a seventh embodiment.

FIG. 20 is a diagram illustrating a manufacturing process of the light source device according to the seventh embodiment.

FIG. 21 is a diagram illustrating a schematic cross-sectional view of a light source device according to an eighth embodiment.

FIG. 22 is a diagram illustrating a manufacturing process of the light source device according to the eighth embodiment.

### DESCRIPTION OF EMBODIMENTS

A configuration of a light source device according to an aspect of the present disclosure, a manufacturing method of a light source device according to an aspect of the present disclosure, and a configuration of a display device according to an aspect of the present disclosure will be described below. In the following embodiments, a case where the light-emitting elements provided in the light source device and the display device according to the aspect of the present disclosure is micro LEDs will be described as an example, but the present disclosure is not limited thereto, and normal size LEDs may be used. Note that a micro LED generally refers to an LED in which an individual LED has a side of 100 μm or less, and a normal size LED generally refers to an LED in which an individual LED has a side longer than 100 μm.

### First Embodiment

### Manufacturing Method of Light Source Device 20

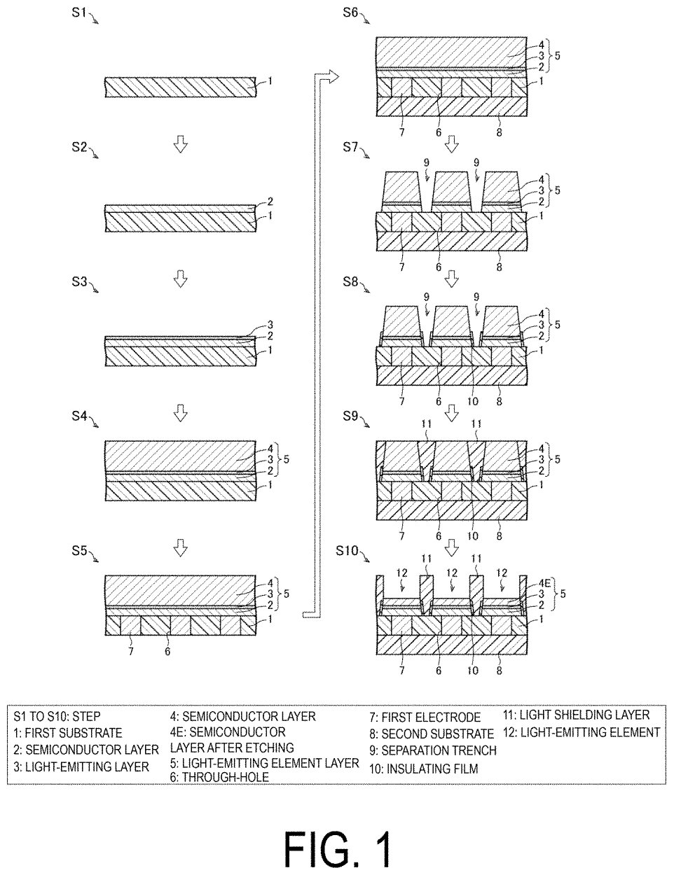

FIG. 1 is a diagram illustrating a manufacturing method of a light source device 20 according to the first embodiment.

In an S1 step illustrated in FIG. 1, for example, a Si base wafer can be used as a first substrate (substrate) 1. In the present embodiment, a case where, the Si base wafer, for example, is used as the first substrate 1 will be described as an example, but the present disclosure is not limited thereto, and an insulating resin substrate, for example, may be used as the first substrate 1.

In an S2 step illustrated in FIG. 1, a semiconductor layer 2 is formed on the first substrate 1. In the present embodiment, since a first electrode (electrode) 7 described below electrically connected to the semiconductor layer 2 is a P electrode, for example, a p-doped GaN layer is formed as the semiconductor layer 2, but the present disclosure is not limited thereto. For example, in a case where the first electrode (electrode) 7 electrically connected to the semiconductor layer 2 is an N electrode, it is only necessary, for example, to form an n-doped GaN layer as the semiconductor layer 2. Note that, as the semiconductor material used for forming the semiconductor layer 2, for example, a GaAsP base, a GaP base, a ZnO base, or the like may be used other than a GaN base. A method of forming the semiconductor layer 2 is not particularly limited, but for example, an epitaxial growth method, a vapor deposition method, a printing method, an application method, a metal organic chemical vapor deposition (MOCVD), or the like can be used.

In an S3 step illustrated in FIG. 1, a light-emitting layer 3 is formed on the semiconductor layer 2. The light-emitting layer 3 may be, for example, a layer that emits light of any one of colors of red, green, or blue. In the present embodiment, a semiconductor material having a band gap corresponding to a wavelength of blue is formed as the light-emitting layer 3 to form the light-emitting layer 3 that emits blue light, but the present disclosure is not limited thereto. For example, in a case where the light-emitting layer 3 that emits green light is formed, a semiconductor material having a band gap corresponding to a wavelength of green may be formed as the light-emitting layer 3, and in a case where the light-emitting layer 3 that emits red light is formed, a semiconductor material having a band gap corresponding to a wavelength of red may be formed as the light-emitting layer 3. A method of forming the light-emitting layer 3 is not particularly limited, but for example, an epitaxial growth method, a vapor deposition method, a printing method, an application method, an MOCVD method, or the like can be used.

In the present embodiment, a case where the light-emitting layer 3 that emits blue light is formed on the entire surface on the semiconductor layer 2 will be described as an example, but the present disclosure is not limited thereto. For example, on the semiconductor layer 2, a light-emitting layer that emits red light may be provided in a first region (a region where a red light-emitting element serving as a first light-emitting element is formed), a light-emitting layer that emits green light may be provided in a second region (a region where a green light-emitting element serving as a second light-emitting element is formed), and a light-emitting layer that emits blue light may be provided in a third region (a region where a blue light-emitting element serving as a third light-emitting element is formed). Note that in such a case, the light-emitting layer can be formed in a predetermined region for each light-emitting layer of each color by using, for example, a photolithographic method. Furthermore, in such a case, in a boundary between the first region and the second region, in a boundary between the second region and the third region, and in a boundary between the third region and the first region, the light-emitting layers that emit adjacent different colors may be formed to overlap with each other, or none of the light-emitting layers that emit adjacent different colors may be formed.

In an S4 step illustrated in FIG. 1, a semiconductor layer 4 is formed on the light-emitting layer 3. In the present embodiment, since the first electrode (electrode) 7 described below electrically connected to the semiconductor layer 2 is the P electrode, for example, an n-doped GaN layer is formed as the semiconductor layer 4, but the present disclosure is not limited thereto. For example, in a case where the first electrode (electrode) 7 electrically connected to the semiconductor layer 2 is an N electrode, for example, a p-doped GaN layer may be formed as the semiconductor layer 4. Note that, as the semiconductor material used for forming the semiconductor layer 4, for example, a GaAsP base, a GaP base, a ZnO base, or the like may be used other than a GaN base. A method of forming the semiconductor layer 4 is not particularly limited, but for example, an epitaxial growth method, a vapor deposition method, a printing method, an application method, an MOCVD method, or the like can be used.

As described above, the S2 step, S3 step, and S4 step illustrated in FIG. 1 correspond to the step of forming the light-emitting element layer 5 in which the semiconductor layer 2, the light-emitting layer 3, and the semiconductor layer 4 are formed in this order from the first substrate 1 side on the surface, of the first substrate (substrate) 1, on one side.

In an S5 step illustrated in FIG. 1, a plurality of first electrodes 7 electrically connected to the semiconductor layer 2 are formed. In the present embodiment, since the first electrode (electrode) 7 is the P electrode, the plurality of first electrodes 7 electrically connected to the semiconductor layer 2, in which the p-doped GaN layer is formed, are formed, but the present disclosure is not limited thereto. Although not illustrated, an annealing (heat treatment) step or the like may be further included in order to improve contact characteristics between the semiconductor layer 2 and the first electrode 7. The S5 step illustrated in FIG. 1 is a step of forming the plurality of first electrodes 7, and in the present embodiment, a case where a through silicon via (TSV) structure is employed in which a plurality of through-holes 6 are formed in the first substrate 1, and each of the plurality of first electrodes 7 electrically connected to the semiconductor layer 2 is formed in a corresponding one of the plurality of through-holes 6 will be described as an example, but the present disclosure is not particularly limited as long as the first electrode 7 can be electrically connected to the semiconductor layer 2. In the present embodiment, since the Si based wafer is used as the first substrate 1, the through-holes 6 can be formed, for example, by ion etching. However, the present disclosure is not limited thereto, and a method of forming the through-holes 6 can be appropriately determined according to a material of the first substrate 1. The first electrode 7 can be formed of, for example, a metal material such as Au, Ag, Cu, Ni, Ti, Pd, or Al.

In the present embodiment, the light-emitting element layer 5 includes the p-doped semiconductor layer 2, the n-doped semiconductor layer 4, and the light-emitting layer 3 serving as an active layer. The semiconductor layer 2 is electrically connected to the first electrode 7 provided on the first substrate 1, and the semiconductor layer 4 is electrically connected to the second electrode (not illustrated). When a current flows between the first electrode 7 and the second electrode (not illustrated), the light-emitting layer 3 emits light. The structure of the light-emitting layer 3 is not limited to a double hetero-junction, but a homo-junction may be used. Additionally, a quantum well structure may be used in which the light-emitting layer 3 serving as the active layer is a quantum well layer.

The thickness of the p-doped semiconductor layer 2 is not particularly limited as long as the p-doped semiconductor layer 2 has properties as the p-doped semiconductor layer, but the thickness is preferably 50 nm or greater and 1000 nm or less, for example, and more preferably 100 nm or greater and 300 nm or less, for example. The thickness of the light-emitting layer 3 is not particularly limited as long as the light-emitting layer 3 has properties as the light-emitting layer, but the thickness is preferably 10 nm or greater and 200 nm or less, for example, and more preferably 50 nm or greater and 100 nm or less, for example. The thickness of the n-doped semiconductor layer 4 is not particularly limited as long as the n-doped semiconductor layer 4 has properties as the n-doped semiconductor layer, but the thickness is preferably 10 μm or less, for example, and more preferably about 5 μm±2 μm.

In an S6 step illustrated in FIG. 1, each of the plurality of first electrodes 7 is electrically connected to a drive circuit (not illustrated) or a wiring line (not illustrated) provided on a second substrate (base substrate) 8. In the S6 step illustrated in FIG. 1, the other surface (the surface on which the light-emitting element layer 5 is not formed) of the first substrate 1 and a surface, on which the drive circuit (not illustrated) or the wiring line (not illustrated) is formed, of the second substrate 8 are disposed to face each other, and each of the plurality of electrodes 7 formed in the corresponding one of the plurality of through-holes 6 is electrically connected to the drive circuit or the wiring line. In the present embodiment, a case where the Si based wafer formed of a semiconductor material (for example, a polysilicon material or the like) for a large-scale integrated circuit (LSI) is used as the second substrate 8 to form the drive circuit, the wiring line, and the like on the second substrate 8 will be described as an example, but the present disclosure is not limited thereto. For example, the second substrate 8 may be an insulating substrate provided with only the wiring line electrically connected to each of the plurality of first electrodes 7, and in this case, the drive circuit may be externally attached. In the present embodiment, the bonding between the first substrate 1 and the second substrate 8 is assumed to be performed by wafer-wafer bonding between the Si base wafers, but the present disclosure is not limited thereto.

In an S7 step illustrated in FIG. 1, a separation trench 9 is formed in the light-emitting element layer 5 to form a plurality of island shape light-emitting element layers 5. Each of the plurality of island shape light-emitting element layers 5 includes the semiconductor layer 2, the light-emitting layer 3, and the semiconductor layer 4. The separation trench 9 can be formed, for example, by etching only a predetermined region of the light-emitting element layer 5. In order to etch only the predetermined region of the light-emitting element layer 5, it is only necessary to form a resist film having high etching resistance only in a portion other than the predetermined region by a photolithographic method or the like, and to then perform etching. Note that while dry etching is preferably used as the etching method in consideration of etching accuracy, wet etching may also be used. Note that although not illustrated in the drawings, the resist film needs to be removed after the separation trench 9 is formed.

An S8 step illustrated in FIG. 1 is an insulating film forming step of forming an insulating film 10 covering at least a portion of each side surface of the plurality of island shape light-emitting element layers 5. The insulating film forming step is a step performed after the step of forming the plurality of island shape light-emitting element layers 5, which is the S7 step illustrated in FIG. 1, and before the step of forming the light shielding layer 11, which is an S9 step illustrated in FIG. 1 and described later. By providing the insulating film 10, effects of preventing a damage to the light-emitting layer 3 due to the subsequent steps and a short circuit between the semiconductor layer 2 and the semiconductor layer 4 can be obtained.

In a case where the light shielding layer 11 is formed of a material having high insulating properties, the insulating film forming step can be omitted as appropriate. In a case where the light shielding layer 11 is formed of a non light reflective material having low insulating properties or a non electrically conductive material having low insulating properties, the insulating film 10 may be formed on the entire side surface of each of the plurality of island shape light-emitting element layers 5. Furthermore, in a case where the light shielding layer 11 is formed of a light reflective material having low insulating properties or a conductive material, as illustrated in the S8 step, the insulating film 10 is preferably formed on the entire side surface of the semiconductor layer 2, the entire side surface of the light-emitting layer 3, and a portion, of a side surface of the semiconductor layer 4, on the light-emitting layer 3 side, of each of the plurality of island shape light-emitting element layers 5 in order to prevent the short circuit between the semiconductor layer 2 and the semiconductor layer 4 above and below the light-emitting layer 3. In this way, by forming the insulating film 10 on only a required portion of the side surface of the plurality of island shape light-emitting element layers 5, a reduction in light reflectivity or a reduction in electrical conductivity of the light shielding layer 11 due to formation of the insulating film 10 can be suppressed, and the short circuit between the semiconductor layer 2 and the semiconductor layer 4 above and below the light-emitting layer 3 can be prevented. Note that although not illustrated, the insulating film 10 may also be formed on the first substrate 1. The insulating film 10 can be formed of, for example, silicon, silicon oxide, silicon nitride, silicon oxynitride, organic insulating material, organic inorganic hybrid insulating material, or the like. In the present embodiment, since the insulating film 10 is formed only on the portion of the side surface of each of the plurality of island shape light-emitting element layers 5, the insulating film 10 can be formed using a photosensitive organic insulating material or an organic inorganic hybrid insulating material by a photolithographic method, but the present disclosure is not limited thereto. For example, silicon oxide or the like may be formed on the entire side surface of each of the plurality of island shape light-emitting element layers 5 and on the first substrate 1 by a vapor deposition method.

The S9 step illustrated in FIG. 1 is a step of forming a light shielding layer 11 made of a material different from the light-emitting element layer 5, at least in the separation trench 9. The light shielding layer 11 can be formed of, for example, a liquid resin material (underfill), a metal material, or the like. The light shielding layer 11 may be formed, for example, in a method of injecting the liquid resin material (for example, a liquid resin material obtained by mixing epoxy resin and light shielding filler) or a liquid metal material to fill the separation trench 9 with the above material, or of filling the separation trench 9 with a metal material by vapor deposition such as sputtering film formation or chemical vapor deposition (CVD). In the present embodiment, the case where the light shielding layer 11 is formed of the metal material and is formed of a light reflective material such as aluminum or silver in consideration of processability and reflectivity will be described as an example, but the present disclosure is not limited thereto. For example, the light shielding layer 11 may be formed of an alloy in which a different metal of approximately several % is mixed with aluminum, or may be formed of a material other than the metal material, as long as processability and reflectivity can be ensured. Furthermore, the light shielding layer 11 may be formed of an insulating material having high insulating properties.

An S10 step illustrated in FIG. 1 is a step of forming a plurality of light-emitting elements 12 each provided with a corresponding one of the plurality of island shape light-emitting element layers 5 having a height less than a height of the light shielding layer 11 by etching the semiconductor layer 4 of each of the plurality of island shape light-emitting element layers 5 after the step of forming the light shielding layer 11 in the separation trench 9, which is the S9 step illustrated in FIG. 1. In this step, the semiconductor layer 4 in the S9 step illustrated in FIG. 1 is etched to obtain an etched semiconductor layer 4E. A surface, of the etched semiconductor layer 4E, on the light-emitting layer 3 side is flatter than a surface, of the etched semiconductor layer 4E, on a side opposite to the light-emitting layer 3 side. A wet etching method or a dry etching method can be used as the etching. The wet etching method includes, for example, a method using an acid such as sulfuric acid, phosphoric acid, nitric acid, or hydrofluoric acid, or a chemical solution of an alkali aqueous solution such as TMAH or a potassium hydroxide aqueous solution, and the dry etching method includes a method using ion beam etching (IBE), reactive ion etching (RIE), or the like.

In the present embodiment, the semiconductor layer 4 is etched by using the wet etching method in order to more easily form surface irregularities of the semiconductor layer 4E serving to more efficiently extract light emitted from the light-emitting layer 3 described below, but the present disclosure is not limited thereto. When the semiconductor layer 4 is etched, for example, a resist film or a silicon oxide film may be provided as a mask having high etching resistance on the light shielding layer 11 as necessary.

Note that, after the S1 to the S4 steps illustrated in FIG. 1 are performed, first, the S7 to an S11 steps illustrated in FIG. 1 may be performed, and then the S5 to S6 steps illustrated in FIG. 1 may be performed.

A step of forming a second electrode 13 described below and subsequent steps are omitted in FIG. 1.

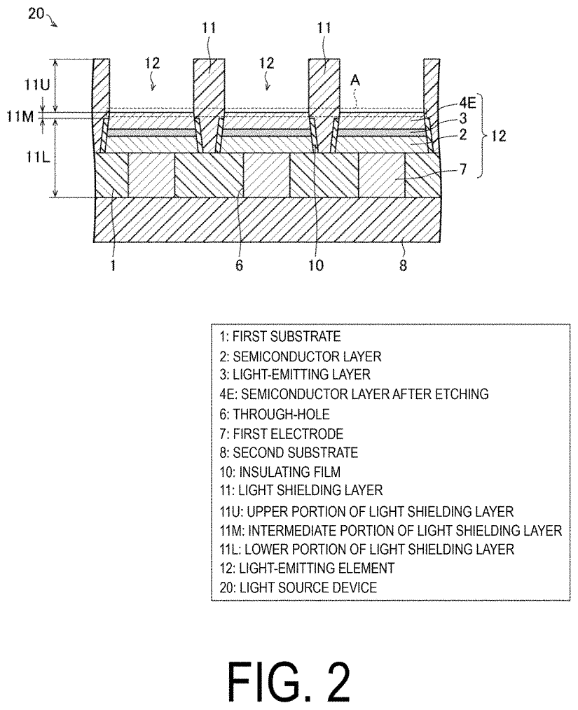

FIG. 2 is a diagram illustrating an overall configuration of the light source device 20 according to the first embodiment, and the light source device 20 is the light source device obtained by the S10 step illustrated in FIG. 1.

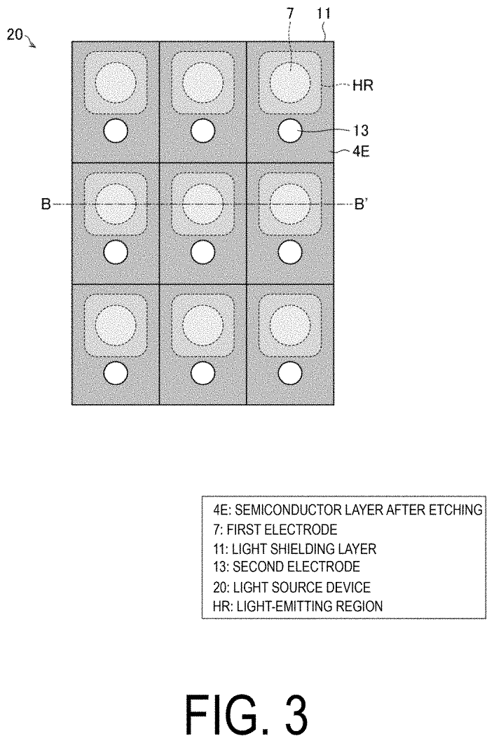

FIG. 3 is a plan view in a case where the light source device 20 according to the first embodiment illustrated in FIG. 2 is provided with the second electrode 13. The cross section of B-B′ in FIG. 3 corresponds to FIG. 2.

The second electrode 13 in the light source device 20 illustrated in FIG. 3 is formed for each light-emitting element 12, similar to the first electrode 7. Note that each of a plurality of the second electrodes 13 illustrated in FIG. 3 is electrically connected to a wiring line not illustrated in the drawing.

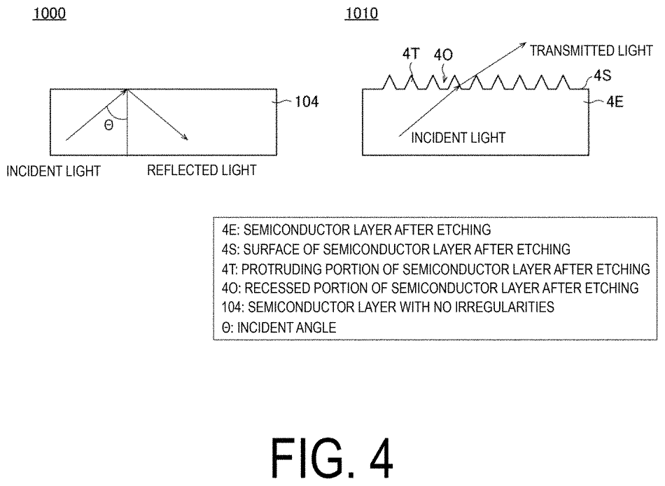

A reference numeral 1000 in FIG. 4 indicates an unetched semiconductor layer 104. A reference numeral 1010 in FIG. 4 indicates the etched semiconductor layer 4E, and is a schematic diagram illustrating the irregularities of a portion A in FIG. 2.

As indicated by the reference numeral 1000 in FIG. 4, in a case of the semiconductor layer 104 whose surface is not formed of irregularities by etching, among incident light irradiated from the semiconductor layer 104 side, light irradiated to the interface between the semiconductor layer 104 and a material such as air or resin having a refractive index lower than that of the semiconductor layer 104 at a specific incident angle Θ or more causes total reflection at the surface of the semiconductor layer 104. Thus, the amount of reflected light thus reflected is large, and it is difficult to improve the light extraction efficiency in a light source device provided with the semiconductor layer 104 having such a flat surface. On the other hand, in a case of the semiconductor layer 4E whose surface 4S is formed of irregularities including a protruding portion 4T and a recessed portion 4O by etching provided in the light source device 20 in the present embodiment, the amount of transmitted light can be increased by suppressing the amount of reflected light that causes the total reflection at the surface of the semiconductor layer 4E among the incident light. Thus, in the light source device 20 provided with the semiconductor layer 4E whose surface 4S is formed of irregularities, the light extraction efficiency can be improved.

In the light source device 20 illustrated in FIG. 2, the drive circuit (not illustrated) or the wiring line (not illustrated) is provided on the second substrate (base substrate) 8, and each of the plurality of light-emitting elements 12 on the surface of the second substrate 8 includes the first electrode 7 electrically connected to the drive circuit or the wiring line, the semiconductor layer 2, the light-emitting layer 3, and the semiconductor layer 4E in this order from the second substrate 8 side. The light shielding layer 11 of the light source device 20 includes an upper portion 11U higher than the height of the light-emitting element 12, a lower portion 11L having a height that combines the thickness of the first electrode 7, the thickness of the semiconductor layer 2, the thickness of the light-emitting layer 3, and the thickness of a portion of the semiconductor layer 4E, and an intermediate portion 11M between the upper portion 11U and the lower portion 11L.

In the present embodiment, since the upper portion 11U of the light shielding layer 11, the intermediate portion 11M, and a portion of the lower portion 11L (other than a portion of the first substrate 1 made of the Si base wafer serving as the insulating layer) are formed of the same material, a side surface of the upper portion 11U, a side surface of the intermediate portion 11M, and a side surface of the portion of the lower portion 11L form a continuous surface. Note that forming a continuous surface means that a surface with no step is formed. In the present embodiment, the case where the side surface of the upper portion 11U of the light shielding layer 11, the side surface of the intermediate portion 11M, and the side surface of the portion of the lower portion 11L are the continuous surface is described as an example, but the present disclosure is not limited thereto, and the side surface of the upper portion 11U of the light shielding layer 11 and the side surface of the intermediate portion 11M may be at least continuous surface.

As described above, in the present embodiment, the case where the light source device 20 is provided with the second substrate (base substrate) 8 as illustrated in FIGS. 1 and 2 is described as an example, but the present disclosure is not limited thereto. For example, the light source device 20 may be a light source device that is not provided with the second substrate (base substrate) 8 as long as the light source device 20 is provided with the light shielding layer 11 formed between each two of the plurality of light-emitting elements 12 to be higher than the height of light-emitting elements 12 as illustrated in FIG. 2. When the light source device not provided with the second substrate (base substrate) 8 is driven, the light source device can be driven by using a separately prepared second substrate including a drive circuit or a wiring line.

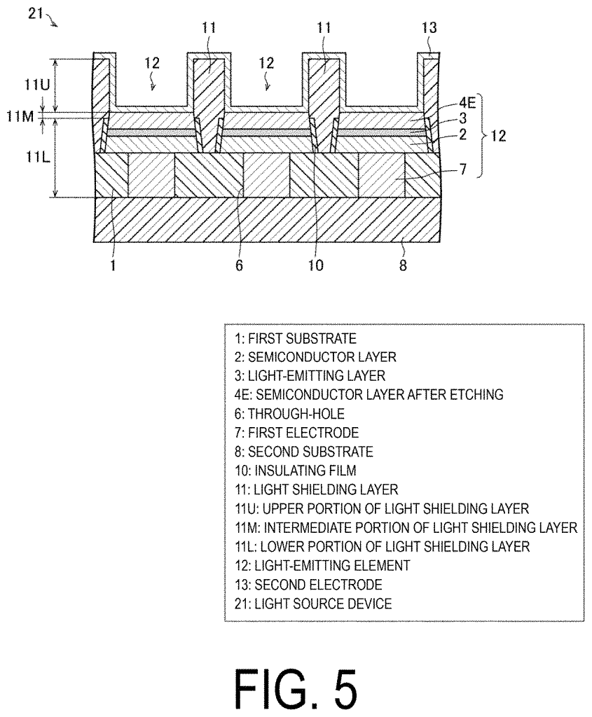

FIG. 5 is a diagram illustrating an overall configuration of a light source device 21 provided with a second electrode 13 in another form. The light source device 21 illustrated in FIG. 5 differs from the light source device 20 illustrated in FIG. 3 which is provided with the second electrode 13 formed for each light-emitting element 12, in that the light source device 21 is provided with the second electrode 13 serving as a common electrode, formed across the plurality of light-emitting elements 12.

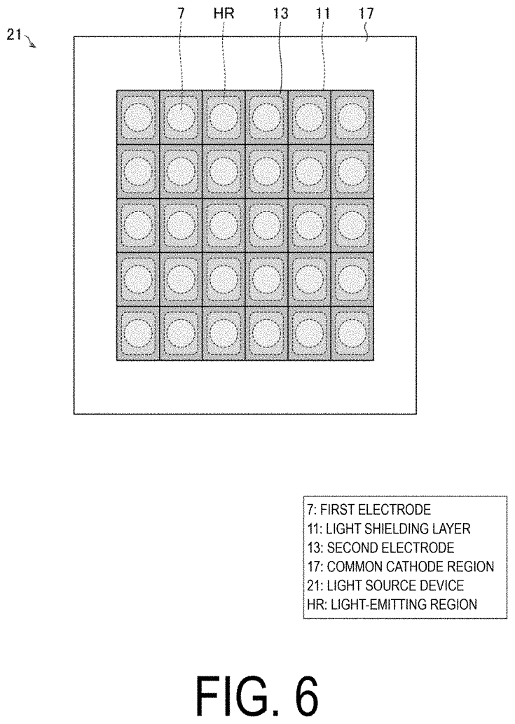

FIG. 6 is a plan view of the light source device 21 illustrated in FIG. 5.

As illustrated in FIGS. 5 and 6, in the light source device 21, exposed surfaces of the plurality of light-emitting elements 12 and the light shielding layer 11 on a side opposite to the second substrate (base substrate) 8 are covered with a conductive material that transmits visible light. A portion formed of the conductive material that transmits visible light is the second electrode 13 serving as an N electrode of the light source device 21. Note that in FIG. 6, HR indicated by a dotted line refers to a light-emitting region. As the conductive material that transmits visible light, for example, a metal oxide can be used, and indium tin oxide (ITO), indium zinc oxide (IZO), or the like is included.

Note that as illustrated in FIG. 6, the second electrode 13 serving as the common electrode of the light source device 21 is electrically connected to a common cathode region 17.

The case where the second electrode 13 is separately provided in the light source device 21 is described as an example, but in a case where the light shielding layer 11 is formed of the light reflective metal material such as aluminum or silver as in the present embodiment, for example, the second electrode 13 need not be provided separately. The reason for this is that since the light shielding layer 11 also has electrical conductivity, the light shielding layer 11 is electrically connected to a portion of a side surface not covered with the insulating film 10 in the semiconductor layer 4E, thereby forming the second electrode serving as the common electrode.

Note that the height of the lower portion 11L of the light shielding layer 11 is preferably set as low as possible within a range in which insulating properties between the first electrodes 7 can be ensured and the short circuit between the semiconductor layer 2 and the semiconductor layer 4E above and below the light-emitting layer 3 can be prevented. According to this configuration, further improvement in the light extraction efficiency and further improvement in the conduction properties between the light shielding layer 11 and the semiconductor layer 4E can be expected.

The shape of the first electrode 7 and the formation example of the second electrode 13 in the light source device 21 illustrated in FIGS. 5 and 6 described above are examples, and the present disclosure is not limited thereto. For example, in FIG. 6, the first electrode 7 is illustrated as being circular in plan view, but may have another shape such as a rectangle, for example.

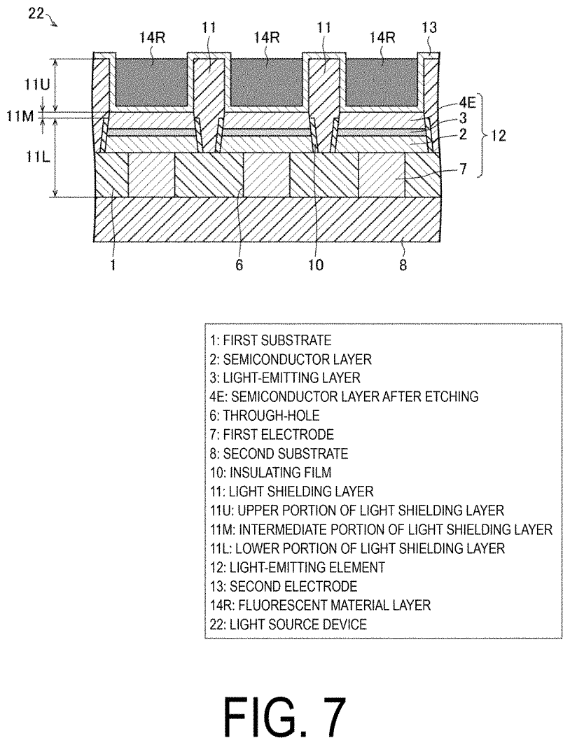

FIG. 7 is a diagram illustrating an overall configuration of a light source device 22 provided with a fluorescent material layer 14R. The light source device 22 illustrated in FIG. 7 differs from the light source device 21 illustrated in FIG. 5 in that the light source device 22 is provided with the fluorescent material layer 14R. The light source device 22 illustrated in FIG. 7 is a monochromatic light-emitting light source device.

As illustrated in FIG. 7, the light source device 22 is provided with the light-emitting layer 3 that emits blue light. The fluorescent material layer 14R that covers each of the plurality of light-emitting elements 12 and is formed to have a film thickness substantially equal to the height of the light shielding layer 11 is included. The fluorescent material layer 14R is a color conversion layer that converts blue light from the light-emitting layer 3 into red light.

In the present embodiment, the light source device 22 that emits red monochromatic light is described as an example, but the present disclosure is not limited thereto. For example, a light source device that emits green monochromatic light can be realized by providing a fluorescent material layer that converts the blue light from the light-emitting layer 3 into green light, instead of the fluorescent material layer 14R. In addition, a light source device that emits blue monochromatic light can be realized by providing a transparent resin layer that transmits the blue light as is from the light-emitting layer 3, instead of the fluorescent material layer 14R.

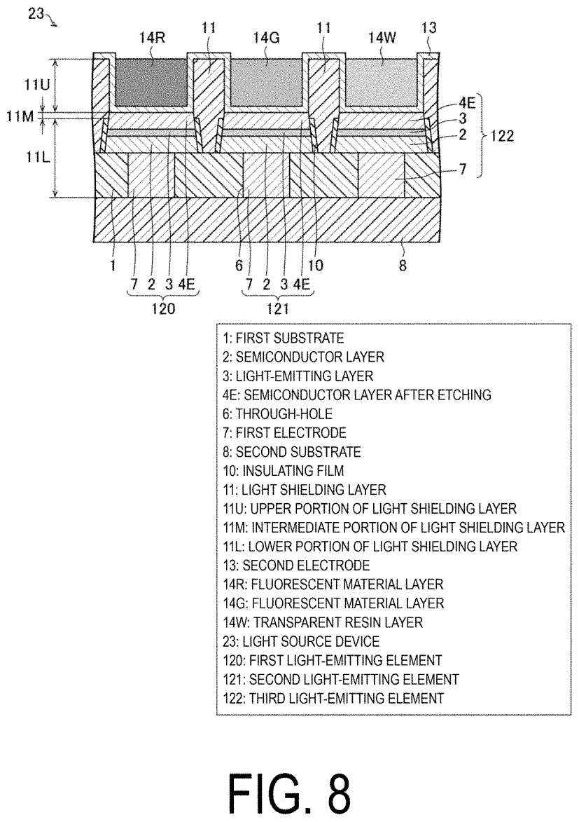

FIG. 8 is a diagram illustrating an example of a display device 23 provided with the light source device according to the first embodiment. The display device 23 illustrated in FIG. 8 differs from the light source device 21 illustrated in FIG. 5 in that the display device 23 is provided with the fluorescent material layer 14R, a fluorescent material layer 14G, and a transparent resin layer 14W.

As illustrated in FIG. 8, the plurality of light-emitting elements 12 include the fluorescent material layer 14R formed on a first light-emitting element 120, the fluorescent material layer 14G formed on a second light-emitting element 121, and the transparent resin layer 14W formed on a third light-emitting element 122, which are disposed adjacent to each other. One pixel of the display device 23 includes a first subpixel, a second subpixel, and a third subpixel; the first subpixel includes the fluorescent material layer 14R and the first light-emitting element 120, the second subpixel includes the fluorescent material layer 14G and the second light-emitting element 121, and the third subpixel includes the transparent resin layer 14W and the third light-emitting element 122. In the display device 23, the first subpixel is a subpixel that emits red light, the second subpixel is a subpixel that emits green light, and the third subpixel is a subpixel that emits blue light, and thus, the first subpixel, the second subpixel, and the third subpixel are subpixels that emit lights having colors different from each other. Since the first light-emitting element 120, the second light-emitting element 121, and the third light-emitting element 122 can individually adjust the luminance (gray scale) of the blue light from the light-emitting layer 3, a display device capable of color display can be realized.

Furthermore, the display device 23 can also be used as a light source device that emits white monochromatic light by adjusting the luminance (gray scale) of the blue light from the light-emitting layers 3 of the first light-emitting element 120, the second light-emitting element 121 and the third light-emitting element 122 such that the colors of lights emitted from the first subpixel, the second subpixel, and the third subpixel of the display device 23 illustrated in FIG. 8 become white light.

### Second Embodiment

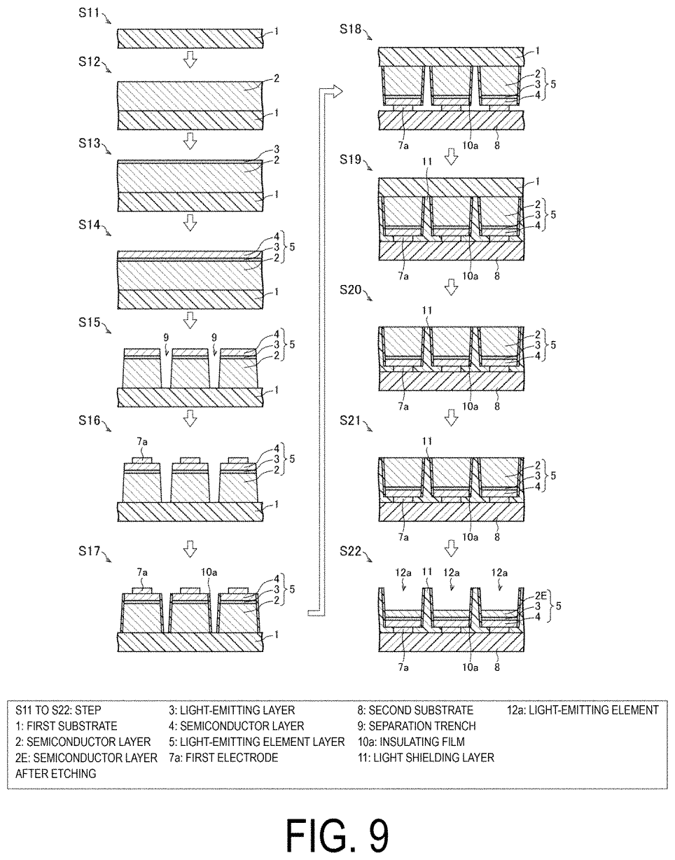

Next, a second embodiment of the present disclosure will be described with reference to FIGS. 9 to 11. A light source device 21a of the present embodiment differs from the light source device described in the first embodiment in that all of the upper portion 11U, the intermediate portion 11M, and the lower portion 11L of the light shielding layer 11 are formed of the same material, a lateral width of the light shielding layer 11 between each two of a plurality of light-emitting elements 12a is narrower as the distance from the second substrate 8 (base substrate) increases, and a sapphire substrate can be used as the first substrate 1. The other components are as described in the first embodiment. For the sake of description, components having functions the same as the functions of the components illustrated in the drawing in the first embodiment are denoted by the same reference numerals, and description thereof will be herein omitted.

FIG. 9 is a diagram illustrating a manufacturing method of the light source device 21a according to the second embodiment.

In the S11 step to the S19 step illustrated in FIG. 9, the second embodiment differs from the first embodiment described above with the assumption that the Si base wafer is used as the first substrate 1, in that a sapphire substrate or a glass substrate can be used as the first substrate 1. Other than this point, since the S11 step to an S14 step illustrated in FIG. 9 correspond to the S1 step to the S4 step illustrated in FIG. 1, and an S15 step illustrated in FIG. 9 corresponds to the S7 step illustrated in FIG. 1, descriptions thereof will be omitted.

An S16 step illustrated in FIG. 9 is a step of forming a plurality of first electrodes 7a, and the plurality of first electrodes 7a electrically connected to the semiconductor layer 4 are formed. In the present embodiment, since the first electrode 7a is a P electrode, the semiconductor layer 4 is a p-doped semiconductor layer, and the semiconductor layer 2 is an n-doped semiconductor layer. Note that although not illustrated, an annealing (heat treatment) step or the like may be further included in order to improve the contact characteristics between the semiconductor layer 4 and the first electrode 7a.

An S17 step illustrated in FIG. 9 is an insulating film forming step of forming an insulating film 10a covering at least a portion of each side surface of the plurality of island shape light-emitting element layers 5. The insulating film forming step is a step performed after the step of forming the plurality of island shape light-emitting element layers 5, which is the S15 step illustrated in FIG. 9, and before the step of forming the light shielding layer 11, which is the S19 step illustrated in FIG. 9 and is described later. In the present embodiment, the insulating film 10a is formed on the entire side surface of each of the plurality of island shape light-emitting element layers 5, but the present disclosure is not limited thereto.

Note that in the present embodiment, a case where the S15 step to the S17 step illustrated in FIG. 9 are performed in order of the S15 step, the S16 step, and the S17 step is described as an example, but the present disclosure is not limited thereto. The order of the S15 step to the S17 step illustrated in FIG. 9 is not particularly limited as long as the S17 step is performed after the S15 step.

An S18 step illustrated in FIG. 9 is a step of electrically connecting each of the plurality of first electrodes 7a to a drive circuit (not illustrated) or a wiring line (not illustrated) provided on the second substrate 8, a surface (one side surface) of the first substrate 1 on which the light-emitting element layer 5 is formed and a surface of the second substrate 8 on which the drive circuit or the wiring line is formed are disposed to face each other, and each of the plurality of first electrodes 7a is electrically connected to the drive circuit or the wiring line. The method of electrically connecting each of the plurality of first electrodes 7a to the drive circuit or the wiring line can be performed by flip-chip bonding using bumps, for example, but the present disclosure is not limited thereto.

An S19 step illustrated in FIG. 9 is a step of forming the light shielding layer 11 performed before the step of removing the first substrate 1, which is an S20 step illustrated in FIG. 9. In this step, a gap including the separation trench 9 is filled with a material different from that of the light-emitting element layer 5 to form the light shielding layer 11. Note that in the S19 step illustrated in FIG. 9, since the light shielding layer 11 is formed in a state in which the first substrate 1 and the second substrate 8 face each other, a liquid resin material or a liquid metal material can be injected into the separation trench 9, and the separation trench 9 can be filled with the above material to form the light shielding layer 11, for example.

The S20 step illustrated in FIG. 9 is a step of removing the first substrate 1, and in a case where the first substrate 1 is a sapphire substrate, a glass substrate, or the like as in the present embodiment, the first substrate 1 can be removed by laser lift-off, polishing, or the like and in a case where the first substrate 1 is the Si base wafer or the like, the first substrate 1 can be removed by etching or polishing.

An S21 step illustrated in FIG. 9 is a step performed after the step of removing the first substrate 1, which is the S20 step illustrated in FIG. 9, and before a step of forming the plurality of light-emitting elements 12, which is an S22 step illustrated in FIG. 9, and is at least one of a step of making the heights of the plurality of island shape light-emitting element layers 5 uniform and a step of making the height of the light shielding layer 11 uniform. Observing the state of the surface from which the first substrate 1 is removed, both the step of making the heights of the plurality of island shape light-emitting element layers 5 uniform and the step of making the height of the light shielding layer 11 uniform may be performed, or only one of them may be performed. Note that, the step of making the heights of the plurality of island shape light-emitting element layers 5 uniform and the step of making the height of the light shielding layer 11 uniform may be performed as one step. The step of making the heights of the plurality of island shape light-emitting element layers 5 uniform and the step of making the height of the light shielding layer 11 uniform are a polishing process, and an example may include a chemical mechanical polishing (CMP), for example, but the present disclosure is not limited thereto.

In a case where the first substrate 1 is removed by the laser lift-off, the surface is preferably leveled by polishing to remove a modified layer generated due to the irradiation of laser light at and near the upper part of the plurality of island shape light-emitting element layers 5 and the light shielding layer 11.

The S22 step illustrated in FIG. 9 is a step of forming the plurality of light-emitting elements 12a. In this step, the semiconductor layer 2 of each of the plurality of island shape light-emitting element layers 5 is etched similar to the S10 step in the above-described FIG. 1, and the plurality of light-emitting elements 12a each provided with a corresponding one of the plurality of island shape light-emitting element layers 5 having a height less than the height of the light shielding layer 11 are formed on the second substrate 8. Note that although not illustrated in the drawing, irregularities including protruding portions and recessed portions may be formed on a surface of an etched semiconductor layer 2E, and in this case, a surface, of the etched semiconductor layer 2E, on the light-emitting layer 3 side is flatter than a surface, of the etched semiconductor layer 2E, on a side opposite to the light-emitting layer 3 side. Thus, in the light source device provided with the semiconductor layer 2E having the surface on which the irregularities are formed, the light extraction efficiency can be improved.

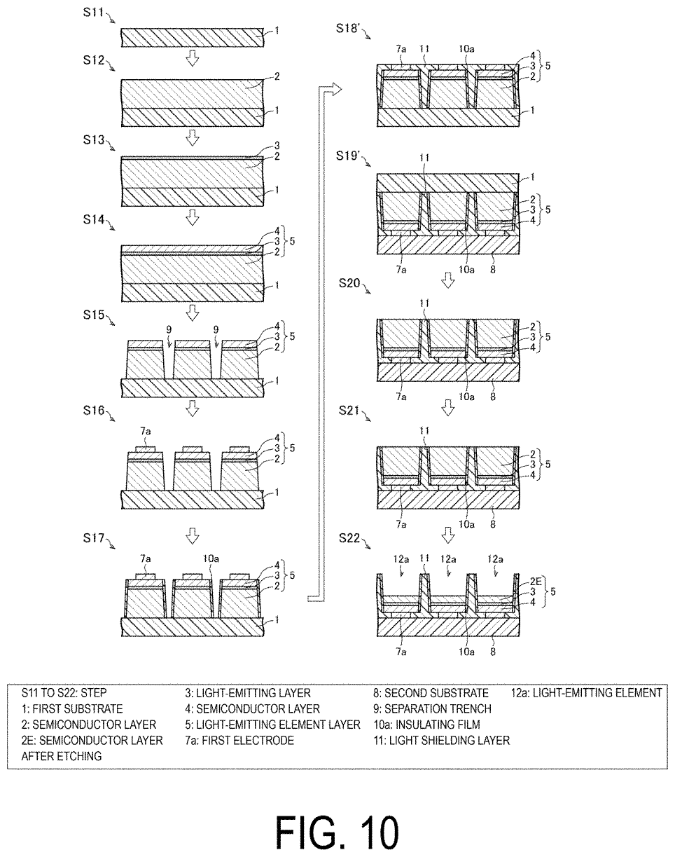

FIG. 10 is a diagram illustrating another manufacturing method of the light source device 21a according to the second embodiment.

Since the S11 step to the S17 step illustrated in FIG. 10 are the S11 step to the S17 step illustrated in FIG. 9, and the S20 step to the S22 step illustrated in FIG. 10 are the S20 step to the S22 step illustrated in FIG. 9, descriptions thereof will be omitted.

Although, in the S18 step and the S19 step illustrated in FIG. 9 described above, the light shielding layer 11 is formed after each of the plurality of first electrodes 7a is electrically connected to the drive circuit (not illustrated) or the wiring line (not illustrated) provided on the second substrate 8, in an S18′ step and an S19′ step illustrated in FIG. 10, each of the plurality of first electrodes 7a is electrically connected to the drive circuit (not illustrated) or the wiring line (not illustrated) provided on the second substrate 8 after the light shielding layer 11 is formed. Thus, since the S18′ step illustrated in FIG. 10 is in a state in which the second substrate 8 is not present, the light shielding layer 11 may be formed, for example, by injecting the liquid resin material or the liquid metal material into the separation trench 9 to fill the separation trench 9 with the above material, or may be formed by filling the separation trench 9 with the metal material by vapor deposition such as sputtering film formation or chemical vapor deposition (CVD).

Note that the forming step of the second electrode 13a described below is omitted in FIGS. 9 and 10.

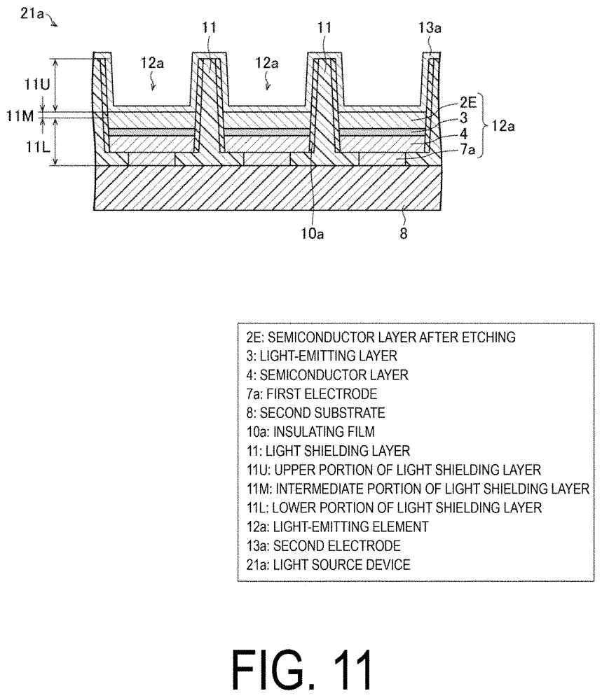

FIG. 11 is a diagram illustrating an overall configuration of a light source device 21a provided with a second electrode 13a.

As illustrated in FIG. 11, in the light source device 21a, the exposed surfaces, of the plurality of light-emitting elements 12a and the light shielding layer 11, on a side opposite to the second substrate (base substrate) 8 are covered with a conductive material that transmits visible light. A portion formed of the conductive material that transmits visible light is the second electrode 13a serving as an N electrode of the light source device 21a.

As illustrated in FIG. 11, in the light shielding layer 11 of the light source device 21a of the present embodiment, all of the upper portion 11U, the intermediate portion 11M, and the lower portion 11L are formed of the same material. In the light shielding layer 11 of the light source device 21a, a lateral width of the light shielding layer 11 between each two of the plurality of light-emitting elements 12a is narrower as the distance from the second substrate 8 (base substrate) increases. In other words, the light shielding layer 11 is formed in a forward taper shape between each two of the plurality of light-emitting elements 12a. By forming the light shielding layer 11 in such a shape, light traveling from the light-emitting layer 3 toward the upper portion 11U of the light shielding layer 11 is reflected upward, and an effect of improving luminance can be obtained.

In the present embodiment, since the step of making the height of the light shielding layer 11 uniform is performed in the S21 step illustrated in FIGS. 9 and 10 described above, the height of the light shielding layer 11 is uniform, as illustrated in FIG. 11.

Note that, since the method of realizing the light source device that emits monochromatic light or the display device by using the light source device 21a of the present embodiment described above is similar to the method described in the first embodiment, descriptions thereof will be omitted.

### Third Embodiment

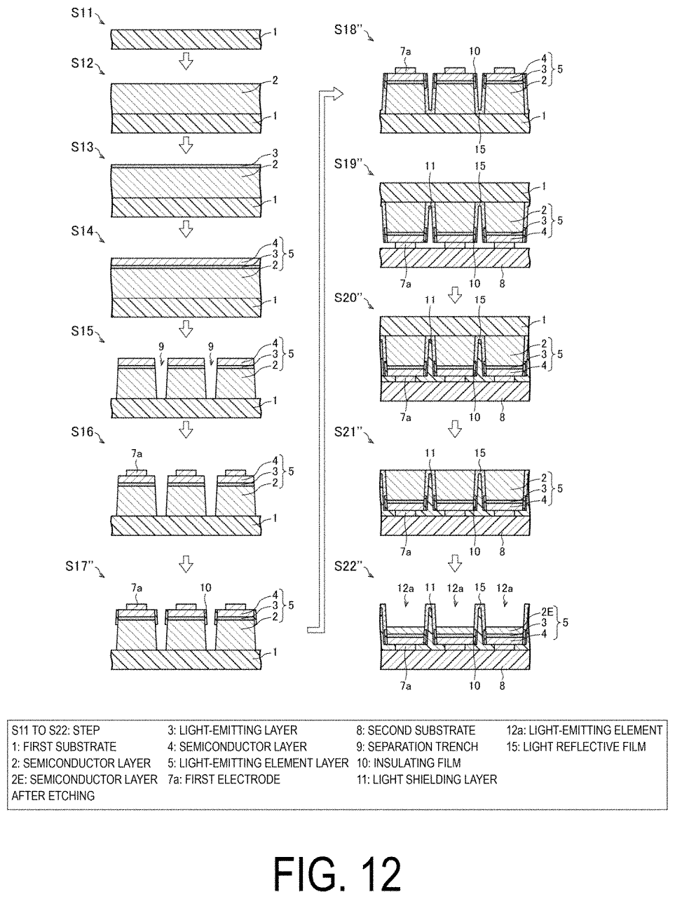

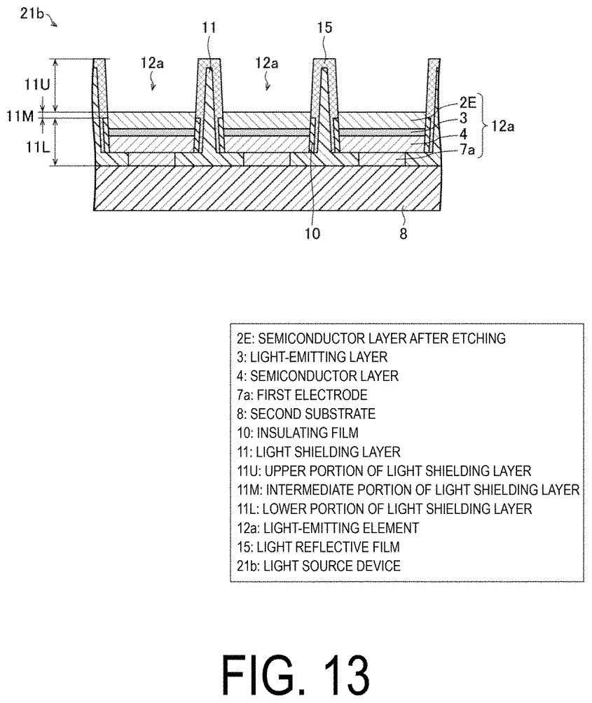

Next, a third embodiment of the present disclosure will be described with reference to FIGS. 12 and 13. A light source device 21b of the present embodiment differs from the light source device described in the second embodiment in that the light shielding layer 11 formed farther from the second substrate (base substrate) 8 than the first electrode 7a is has a portion covered with a light reflective film 15. The other components are as described in the second embodiment. For the sake of description, components having functions the same as the functions of the components illustrated in the drawings in the second embodiment are denoted by the same reference numerals, and description thereof will be herein omitted.

FIG. 12 is a diagram illustrating a manufacturing method of a light source device 21b according to the third embodiment.

Since the S11 step to the S16 step illustrated in FIG. 12 correspond to the S11 step to the S16 step, respectively, illustrated in FIGS. 9 and 10, descriptions thereof will be omitted.

In the present embodiment, since the first electrode 7a is a P electrode, the semiconductor layer 4 is a p-doped semiconductor layer, and the semiconductor layer 2 is an n-doped semiconductor layer.

An S17″ step illustrated in FIG. 12 is an insulating film forming step of forming an insulating film 10 covering at least a portion of each side surface of the plurality of island shape light-emitting element layers 5. The insulating film forming step is a step performed after a step of forming the plurality of island shape light-emitting element layers 5, which is the S15 step illustrated in FIG. 12, and before a step of forming the light reflective film 15, which is an S18″ step illustrated in FIG. 12 to be described later. By providing the insulating film 10, effects of preventing a damage to the light-emitting layer 3 in the subsequent steps and a short circuit between the semiconductor layer 2 and the semiconductor layer 4 can be obtained.

In the present embodiment, since a metal material or the like having low insulating properties is used as the light reflective film 15, the insulating film 10 is preferably formed on an entire side surface of the semiconductor layer 4, an entire side surface of the light-emitting layer 3, and a portion, of a side surface of the semiconductor layer 2, on the light-emitting layer 3 side, of each of the plurality of island shape light-emitting element layers 5 as illustrated in the S17″ step, in order to prevent the short circuit between the semiconductor layer 2 and the semiconductor layer 4 above and below the light-emitting layer 3.

Note that in a case where a material having high insulating properties is used as the light reflective film 15, the S17″ step illustrated in FIG. 12 can be omitted as appropriate.

The S18″ step illustrated in FIG. 12 is a light reflective film forming step in which the light reflective film 15 made of a material that reflects light is formed into the separation trench 9. As in the present embodiment, in a case where the S17″ step illustrated in FIG. 12 is included, the S18″ step can be performed after the S17″ step illustrated in FIG. 12 and before a step of electrically connecting each of the plurality of first electrodes 7a to the drive circuit (not illustrated) or the wiring line (not illustrated) provided on the second substrate (base substrate) 8, which is an S19″ step illustrated in FIG. 12.

On the other hand, in a case where the S17″ step illustrated in FIG. 12 is not included, the light reflective film forming step, which is the S18″ step illustrated in FIG. 12, can be performed after the step of forming the plurality of island shape light-emitting element layers 5, which is the S15 step illustrated in FIG. 12, and before the step of electrically connecting each of the plurality of first electrodes 7a to the drive circuit (not illustrated) or the wiring line (not illustrated) provided on the second substrate (base substrate) 8, which is the S19″ step illustrated in FIG. 12.

The light reflective film 15 is preferably formed of a material having high reflectivity such as aluminum or silver, for example. Note that since vapor deposition such as sputtering film formation or chemical vapor deposition (CVD) can be used as the forming method, the S18″ step illustrated in FIG. 12 needs to be performed before the S19″ step illustrated in FIG. 12.

Note that since the S19″ step to an S21″ step illustrated in FIG. 12 correspond to the S18 step to the S20 step, respectively, illustrated in FIG. 9, and an S22″ step illustrated in FIG. 12 corresponds to the S22 step illustrated in FIG. 9, descriptions thereof will be omitted.

FIG. 13 is a diagram illustrating an overall configuration of the light source device 21b.

As illustrated in FIG. 13, in the light source device 21b, a case where the entire light shielding layer 11 formed farther from the second substrate (base substrate) 8 than the first electrode 7a is covered with the light reflective film 15 will be described as an example, but the present disclosure is not limited thereto, and a portion of the light shielding layer 11 formed farther from the second substrate (base substrate) 8 than the first electrode 7a may have a portion covered with the light reflective film 15. According to such a configuration, by reflecting the light irradiated to the light shielding layer 11, the light source device 21b with improved light extraction efficiency can be realized. In the present embodiment, the light reflective film 15 is formed of a light reflective metal material such as aluminum or silver, for example. Thus, since the light reflective film 15 also has electrical conductivity, the light reflective film 15 is electrically connected to a portion in which a side surface is not covered with the insulating film 10 in the semiconductor layer 2E, which is a layer electrically separated, so that the light reflective film 15 can also function as the second electrode serving as the common electrode. Accordingly, the second electrode need not be separately provided.

Note that the height of the lower portion 11L of the light shielding layer 11 is preferably set as low as possible within a range in which insulating properties between the first electrodes 7a can be ensured and the short circuit between the semiconductor layer 2E and the semiconductor layer 4 above and below the light-emitting layer 3 can be prevented. According to this configuration, further improvement in the light extraction efficiency and further improvement in the conduction properties between the light reflective film 15 and the semiconductor layer 2E can be expected.

Note that also in the configuration of the light source device 20 (illustrated in FIGS. 1 and 2) in the first embodiment described above, in a case where the shielding layer 11 is formed of a non light reflective material, the light reflective film 15 can be provided. In this case, in a case where the S8 step illustrated in FIG. 1 is not included, the light reflective film forming step, which is the S18″ step illustrated in FIG. 12, can be performed after the step of forming the plurality of island shape light-emitting element layers 5, which is the S7 step illustrated in FIG. 1, and before the step of forming the light shielding layer 11, which is the S9 step illustrated in FIG. 1. On the other hand, in a case where the S8 step illustrated in FIG. 1 is included, the light reflective film forming step, which is the S18″ step illustrated in FIG. 12, can be performed after the S8 step illustrated in FIG. 1 and before the step of forming the light shielding layer 11, which is the S9 step illustrated in FIG. 1.

### Fourth Embodiment

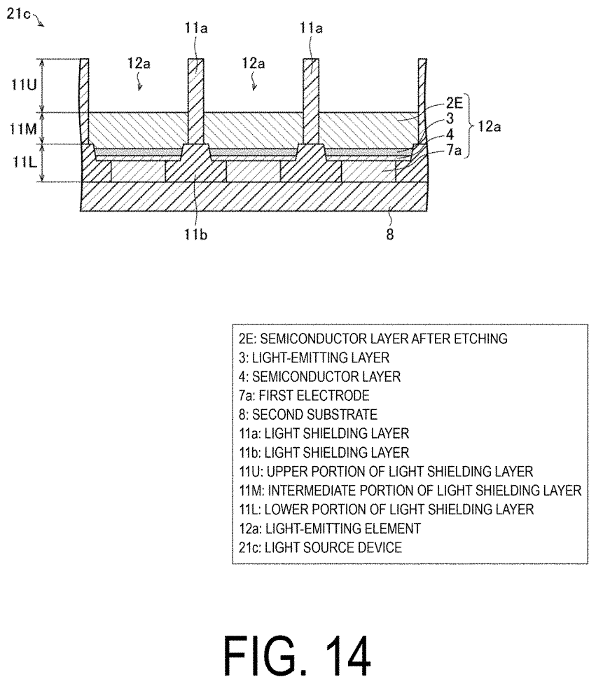

Next, a fourth embodiment of the present disclosure will be described with reference to FIG. 14. FIG. 14 is a diagram illustrating an overall configuration of a light source device 21c according to a fourth embodiment. The light source device 21c of the present embodiment differs from the light source devices described in the first to the third embodiments, in that a light shielding layer 11a corresponding to the upper portion 11U and the intermediate portion 11M is formed of a light reflective material or a conductive material, and a light shielding layer 11b corresponding to the lower portion 11L is formed of an insulating material. The other components are as described in the first to the third embodiments. For the sake of description, components having functions the same as the functions of the components illustrated in the drawings in the first to the third embodiments are denoted by the same reference numerals, and descriptions thereof will be herein omitted.

As illustrated in FIG. 14, the light shielding layers 11a and 11b provided in the light source device 21c include the upper portion 11U that is higher than the height of the light-emitting element 12a, the lower portion 11L having a height that combines the thickness of the first electrode 7a, the thickness of the semiconductor layer 4, the thickness of the light-emitting layer 3, and the thickness of a portion of the semiconductor layer 2E, and the intermediate portion 11M between the upper portion 11U and the lower portion 11L. The light shielding layer 11a corresponding to the upper portion 11U and the intermediate portion 11M is formed of the light reflective material or the conductive material, and the light shielding layer 11b corresponding to the lower portion 11L is formed of the insulating material.

In the present embodiment, since the first electrode 7a is a P electrode, the semiconductor layer 4 is a p-doped semiconductor layer, and the semiconductor layer 2E is an n-doped semiconductor layer.

In the present embodiment, the light shielding layer 11a is formed of a metal material having high reflectivity such as aluminum or silver, for example. According to such a configuration, by reflecting the light incident on the light shielding layer 11, the light source device 21c with improved light extraction efficiency can be realized. Since the light shielding layer 11a also has high electrical conductivity, the light shielding layer 11a functions as the second electrode serving as the common electrode in contact with a portion of the semiconductor layer 2E. Accordingly, the second electrode need not be separately provided.

Note that the height of the lower portion 11L is preferably set as low as possible within a range in which the short circuit between the semiconductor layer 2E and the semiconductor layer 4 above and below the light-emitting layer 3 can be prevented. According to this configuration, further improvement in the light extraction efficiency and further improvement in the conduction properties between a semiconductor layer 2E portion in contact with the light shielding layer 11a and the light shielding layer 11a can be expected.

In a case where the light shielding layer 11a is formed of the non electrically conductive light reflective material, it is only needed to separately provide the second electrode.

In a case where the light shielding layer 11a is formed of the non reflective electrically conductive material, the second electrode need not be separately provided.

### Fifth Embodiment

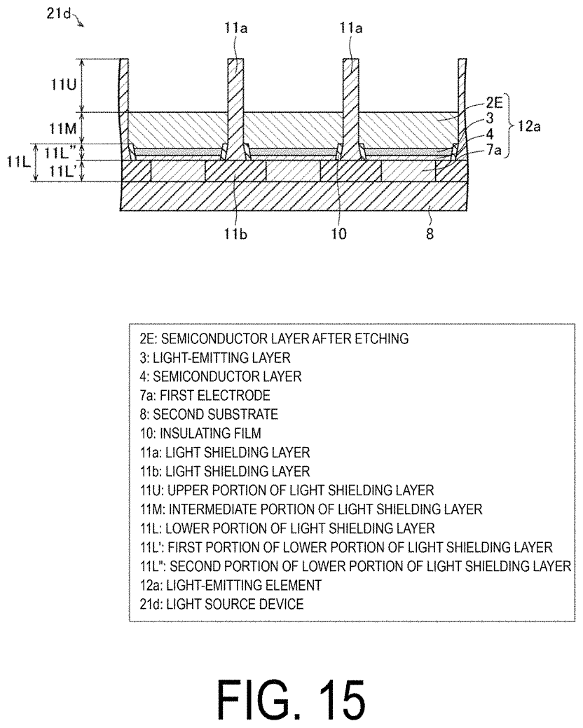

Next, a fifth embodiment of the present disclosure will be described with reference to FIG. 15. FIG. 15 is a diagram illustrating an overall configuration of a light source device 21d according to the fifth embodiment. The light source device 21d of the present embodiment, differs from the light source device described in the fourth embodiment, in that the light shielding layer 11b corresponding to a first portion 11L′ of the lower portion 11L is formed of an insulating material, the light shielding layer 11a corresponding to a second portion 11L″ of the lower portion 11L, the intermediate portion 11M, and the upper portion 11U is formed of the light reflective material or the conductive material, and the insulating film 10 is formed on a side surface of the second portion 11L″ of the lower portion 11L. The other components are as described in the fourth embodiment. For the sake of description, components having functions the same as the functions of the components illustrated in the drawings in the fourth embodiment are denoted by the same reference numerals, and description thereof will be herein omitted.

As illustrated in FIG. 15, the light shielding layers 11a and 11b provided in the light source device 21d include the upper portion 11U that is higher than the height of the light-emitting element 12a, the lower portion 11L having a height that combines the thickness of the first electrode 7a, the thickness of the semiconductor layer 4, the thickness of the light-emitting layer 3, and the thickness of a portion of the semiconductor layer 2E, and the intermediate portion 11M between the upper portion 11U and the lower portion 11L. The light shielding layer 11b corresponding to the first portion 11L′ of the lower portion 11L is formed of the insulating material and is an insulating layer provided between the first electrodes 7a. The light shielding layer 11a corresponding to the second portion 11L″ of the lower portion 11L, the intermediate portion 11M, and the upper portion 11U are formed of the light reflective material or the conductive material.

In the present embodiment, since the first electrode 7a is a P electrode, the semiconductor layer 4 is a p-doped semiconductor layer, and the semiconductor layer 2E is an n-doped semiconductor layer.

In the present embodiment, the light shielding layer 11a is formed of a metal material having high reflectivity such as aluminum or silver, for example. Since the light shielding layer 11a is formed up to the side surface portion of the light-emitting layer 3, the light source device 21d with further improved light extraction efficiency can be realized by reflecting the light incident on the light shielding layer 11. Since the light shielding layer 11a is formed up to the side surface portion of the light-emitting layer 3, light emitted from the light-emitting layer 3 in a lateral direction of the drawing can be reflected to the semiconductor layer 2E side, so that the light source device 21d with improved luminance can be realized. Since the light shielding layer 11a also has high electrical conductivity, the light shielding layer 11a functions as the second electrode serving as the common electrode in contact with a portion of the semiconductor layer 2E. Accordingly, the second electrode need not be separately provided.

In a case where the light shielding layer 11a is formed of the non electrically conductive light reflective material, it is only needed to separately provide the second electrode.

In a case where the light shielding layer 11a is formed of the non reflective electrically conductive material, the second electrode need not be separately provided.

### Sixth Embodiment

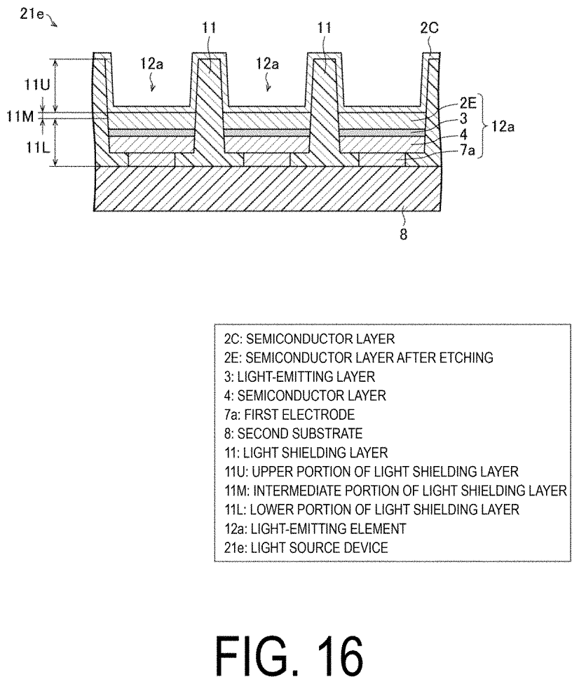

Next, a sixth embodiment of the present disclosure will be described with reference to FIGS. 16 to 18. Light source devices 21e and 21f of the present embodiment differ from the light source devices described in the fourth and fifth embodiments in that exposed surfaces, of the plurality of light-emitting element 12a and the light shielding layer 11, on a side opposite to the second substrate (base substrate) 8 are provided with a semiconductor layer (third semiconductor layer) 2C connecting together the semiconductor layers 2E each provided in a corresponding one of the plurality of light-emitting elements 12a. The other components are as described in the fourth and fifth embodiments. For the sake of description, components having functions the same as the functions of the components illustrated in the drawings in the fourth and fifth embodiments are denoted by the same reference numerals, and description thereof will be herein omitted.

FIG. 16 is a diagram illustrating an example in a case where the light source device 21e according to the sixth embodiment is provided with the second semiconductor layer 2C instead of the second electrode.

As illustrated in FIG. 16, in the light source device 21e, exposed surfaces, of the plurality of light-emitting element 12a and the light shielding layer 11, on a side opposite to the second substrate (base substrate) 8 is provided with the semiconductor layer 2C connecting together the semiconductor layers 2E each provided in a corresponding one of the plurality of light-emitting elements 12a to cover the entire of the plurality of light-emitting elements 12a and the light shielding layer 11. In the light source device 21e, the semiconductor layer 2C functions as the second electrode.

In the present embodiment, since the first electrode 7a is a P electrode, the semiconductor layer 4 is a p-doped semiconductor layer, and the semiconductor layer 2E is an n-doped semiconductor layer.

In the present embodiment, a case where the semiconductor layer 2C is formed of the same material as the semiconductor layer 2E will be described as an example, but the present disclosure is not limited thereto as long as the material can be used instead of the electrode.

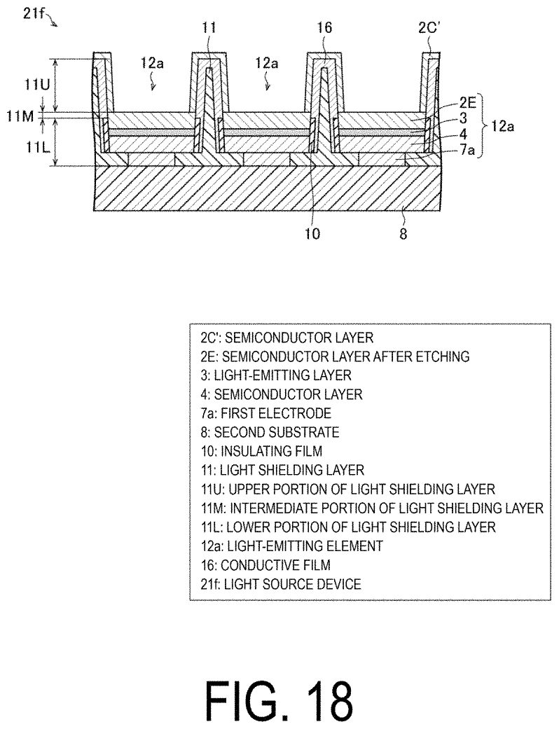

In the light source device 21e, the case where the semiconductor layer 2C is provided to cover the entire of the plurality of light-emitting elements 12a and the light shielding layer 11 is described as an example, but the present disclosure is not limited thereto, and the semiconductor layer 2 may be formed to cover only the light shielding layer 11, as long as the semiconductor layers 2E each provided in a corresponding one of the plurality of light-emitting elements 12a can be connected together, as in a light source device 21f illustrated in FIG. 18 to be described later.

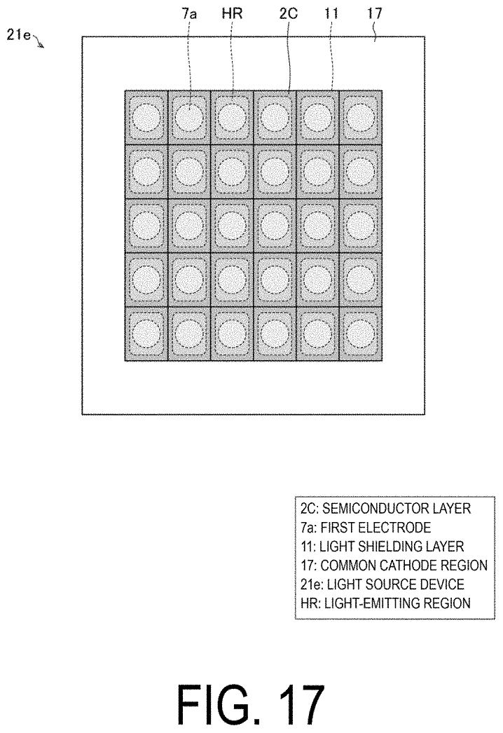

FIG. 17 is a plan view of the light source device 21e according to the sixth embodiment illustrated in FIG. 16.

As illustrated in FIGS. 16 and 17, in the light source device 21e, exposed surfaces of the plurality of light-emitting elements 12a and the light shielding layer 11 on a side opposite to the second substrate (base substrate) 8 are covered with the semiconductor layer 2C. The semiconductor layer 2C serves as the second electrode of the light source device 21e. Note that in FIG. 17, HR indicated by a dotted line refers to a light-emitting region. Note that as illustrated in FIG. 17, the semiconductor layer 2C serving as the common electrode of the light source device 21e is electrically connected to the common cathode region 17.

According to the light source device 21e, by electrically connecting the semiconductor layer 2E entirely using the semiconductor layer 2C, the pixel defects due to poor bonding can be reduced and yield can be improved.

FIG. 18 is a diagram illustrating an overall configuration of a light source device 21f of a modification example of the sixth embodiment.

As illustrated in FIG. 18, in the light source device 21f, the entire side surface of the light shielding layer 11 other than the light shielding layer 11 formed between the first electrodes 7a is covered with a conductive film 16. Since the conductive film 16 has high electrical conductivity, the second electrode serving as the common electrode is formed in contact with a portion of the semiconductor layer 2E. As with the light source device 21f, in a case where an electrical property of the second electrode is sufficiently obtained by the conductive film 16, a semiconductor layer 2C′ may be formed to cover only the light shielding layer 11, or the semiconductor layer 2C′ need not be formed. In this case, the semiconductor layer 2E and the semiconductor layer 2C′ may be of the same material.

### Seventh Embodiment

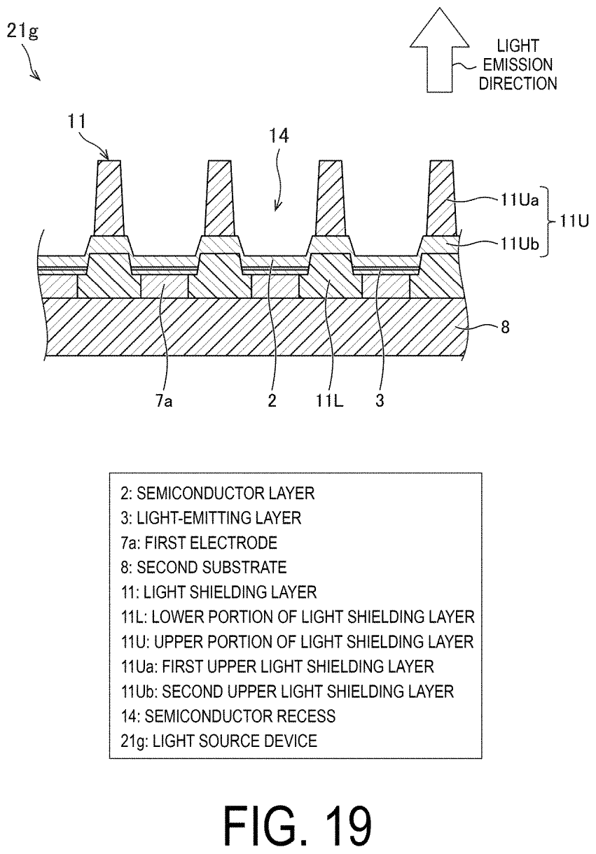

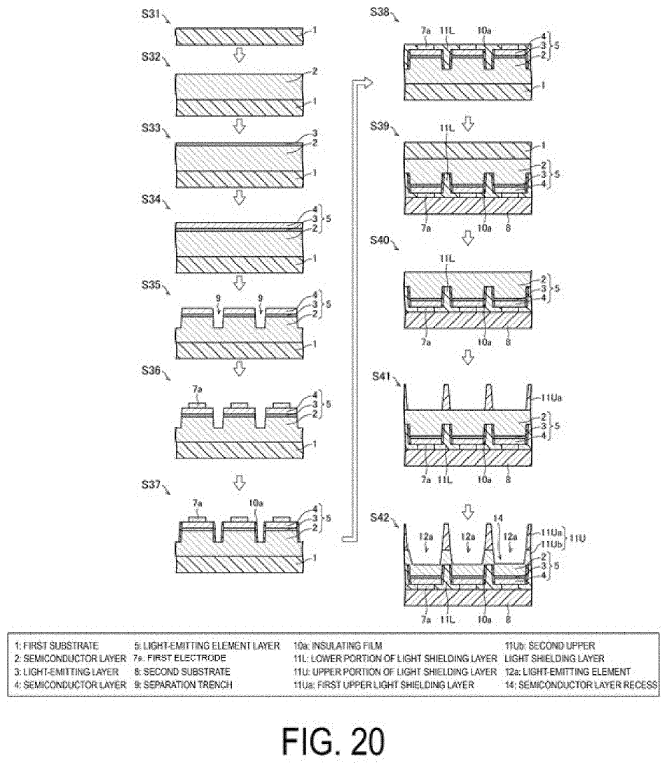

Next, a seventh embodiment of the present disclosure will be described with reference to FIGS. 19 and 20. A light source device 21g according to the present embodiment will be described. In the embodiments 1 to 6, the upper portion 11U of the light shielding layer 11 protruding upward is formed by solely etching the semiconductor layer 2, but the present configuration differs in that a portion of the upper portion 11U of the light shielding layer 11 is formed by etching the semiconductor layer 2.

As illustrated in FIG. 19, in the light source device 21g, the upper portion 11U of the light shielding layer 11 includes a first upper light shielding layer 11Ua and a second upper light shielding layer 11Ub. The second upper light shielding layer 11Ub is formed by etching the semiconductor layer 2 similarly to the previous embodiments. On the other hand, the first upper light shielding layer 11Ua is a protruding pattern formed on a surface, of the semiconductor layer 2, on the light emission side, and is a portion formed by the dry etching or the lift-off method of the metal film. By combining both, a higher light shielding layer can be formed. When the light emitting direction is viewed as upward, the upper surface of the semiconductor layer 2 is higher than the other portion in the upper light shielding layer portion.

According to the present configuration, since a metal film such as aluminum or silver having high electrical conductivity and high reflectivity for visible light can be used as the first upper light shielding layer 11Ua, there is an advantage that the first upper light shielding layer 11Ua can be used as a wiring line layer.

FIG. 20 is a diagram illustrating a manufacturing method of the light source device 21g according to the seventh embodiment.

An S31 step to an S34 step illustrated in FIG. 20 are the same as the manufacturing process S11 to S14 of the second embodiment illustrated in FIG. 9. Note that the first substrate 1 is not limited to the sapphire substrate or the glass substrate, and a silicon substrate or the like can be used.

In an S35 step illustrated in FIG. 20, the separation trench 9 is formed in the light-emitting element layer 5 to form the plurality of island shape light-emitting element layers 5. Each of the plurality of island shape light-emitting element layers 5 includes the semiconductor layer 2, the light-emitting layer 3, and the semiconductor layer 4. This point is similar to S15 in FIG. 9, but the difference is that the separation trench 9 reaches the first substrate surface in S15, whereas a portion of the semiconductor layer 2 is left in the present configuration. It is advantageous that the portion of the semiconductor layer 2 that is continuously connected between the light-emitting elements can be used as a part of the wiring line.

An S36 step illustrated in FIG. 20 is similar to S16 in FIG. 9. It is the step of forming the plurality of first electrodes 7a, and the plurality of first electrodes 7a electrically connected to the semiconductor layer 4 is formed.

An S37 step illustrated in FIG. 20 is similar to the S17 step illustrated in FIG. 9, and is the insulating film forming step of forming an insulating film 10a covering at least a portion of each side surface of the plurality of island shape light-emitting element layers 5.

An S38 step illustrated in FIG. 20 is a step of embedding the light shielding layer into the separation trench 9 to form the lower portion 11L of the light shielding layer 11. The present configuration differs in that the light shielding layer 11 is formed after performing of bonding to the second substrate 8 (S19) in FIG. 9, whereas the light shielding layer 11 is formed before the performing of the bonding in the present configuration. In the bonding of an S39, it is necessary to reliably expose the first electrode 7a from the lower portion 11L of the light shielding layer 11 in order to obtain good bonding. Thus, in the formation of the lower portion 11L of the light shielding layer 11, the first electrode 7a may be exposed by performing a photolithography process to form the lower portion 11L of the light shielding layer 11 only in the separation trench 9 on the first electrode 7a, or by performing etching back after uniformly forming the light shielding layer.

The S39 step illustrated in FIG. 20 is a step of electrically connecting each of the plurality of first electrodes 7a to the drive circuit (not illustrated) or the wiring line (not illustrated) provided on the second substrate 8, similar to the S18 step illustrated in FIG. 9.

S40 illustrated in FIG. 20 is a step of removing the first substrate 1 and making the heights of the plurality of island shape light-emitting element layers 5 uniform, similar to the S20 step and the S21 step illustrated in FIG. 9. In present configuration, since the semiconductor layer 2 is left on the front surface of the second substrate when the first substrate 1 is removed, there is an advantage that occurrence of a defect of the light-emitting element can be prevented when the first substrate 1 is removed.

S41 illustrated in FIG. 20 is a step that does not exist in FIG. 9, and in the present step, the first upper light shielding layer 11Ua serving as the upper portion 11U of the light shielding layer 11 is formed. For example, a metal thin film to serve as the first upper light shielding layer 11Ua is deposited to form the metal thin film into a wall shape by using the photolithography technique and the dry etching technique. Alternatively, the metal thin film may be formed into the wall shape by using the lift-off method. In a plan view, the first upper light shielding layer 11Ua is disposed on the outer periphery of the light-emitting element 12a, and is connected in a lattice pattern in a case where the light-emitting elements 12a are disposed in an array shape. Thus, in a case where aluminum or silver having high electrical conductivity is used as the first upper light shielding layer 11Ua, the first upper light shielding layer 11Ua can also be used as the wiring line layer. Note that the first upper light shielding layer 11Ua is not limited to the metal material. It may be configured only of a resin material having light shielding properties. The light shielding properties may be realized by forming a transparent body configured of an inorganic insulating film such as SiO₂ or an organic film such as a negative resist, and then covering the transparent body with a metal film.

In S42 illustrated in FIG. 20, the surface of the semiconductor layer 2 is etched to form a semiconductor recess 14. The second upper light shielding layer 11Ub is formed below the first upper light shielding layer 11Ua. The semiconductor recess 14 may but does not need to be in contact with the lower portion 11L of the light shielding layer 11. However, since the first upper light shielding layer 11Ua and the semiconductor layer 2 need to be electrically connected to each other, the second upper light shielding layer 11Ub needs to be connected to the semiconductor layer 2.

In the first to sixth embodiments, the upper portion 11U of the light shielding layer 11 is caused to protrude upward by etching the semiconductor layer 2 of each of the plurality of island shape light-emitting element layers 5. In the present configuration, a portion of the upper portion 11U of the light shielding layer 11 is formed as a protruding pattern that originally protrudes on the semiconductor layer 2, and forms, together with the formation of the semiconductor recess 14, the upper portion 11U of the light shielding layer 11 that is even higher. In the present configuration, the light shielding layer having a desired height can be formed by forming a relatively low pattern and etching the semiconductor layer 2 relatively small.

Wavelength conversion can be performed by disposing the phosphor layer 14R as illustrated in FIG. 7 in a bathtub shape region surrounded by the upper portion 11U of the light shielding layer 11, or full color display can be realized by disposing the phosphor layers 14R and 14G and the transparent resin layer 14W illustrated in FIG. 8.

According to the present configuration, effects similar to those of the first embodiment can also be realized.

### Eighth Embodiment

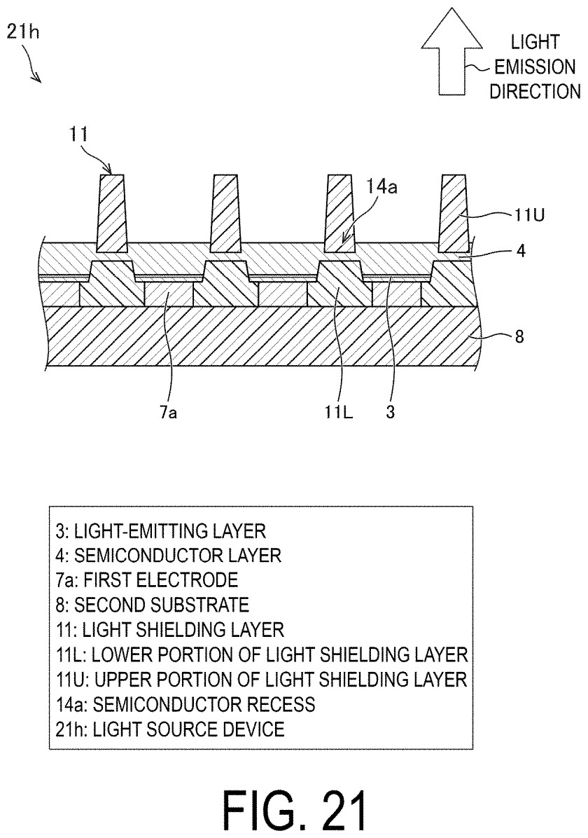

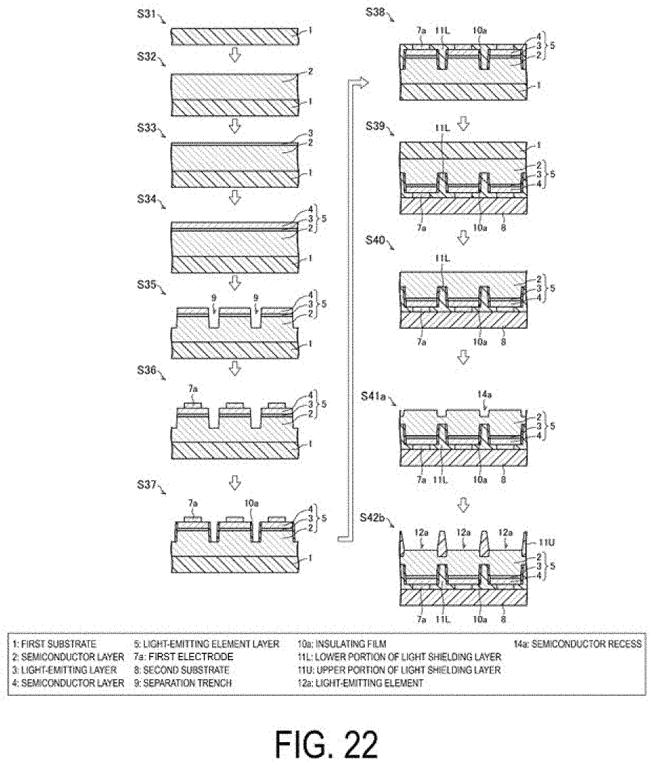

Next, an eighth embodiment of the present disclosure will be described with reference to FIGS. 21 and 22. The manufacturing process of the present embodiment is similar to that of the seventh embodiment, and combines the formation of the protruding pattern and the formation of the semiconductor recess. However, the purpose of combining is different.

FIG. 21 illustrates a schematic cross-sectional view of a light source device 21 h according to the present embodiment. The semiconductor recess 14a is provided in a periphery of the light-emitting element 12a, in other words, in the lower portion of the upper portion 11U of the light shielding layer 11. The upper portion 11U of the light shielding layer 11 is a protruding pattern similar to that of the first upper light shielding layer 1111a in the seventh embodiment. In such a configuration, by forming the semiconductor layer 2 continuously connected between the light-emitting elements, a light source device with less defects can be realized and optical crosstalk between the light-emitting elements can be reduced. When the light emitting direction is viewed as upward the upper surface of the semiconductor layer 2 is lower than the other portion in the upper light shielding layer portion.

Next, the manufacturing process will be described with referring to FIG. 22. Since S31 to S40 are the same as those in the seventh embodiment, and descriptions thereof will be omitted.

S41a illustrated in FIG. 22 is a step of forming a semiconductor recess 14a in the surface of the semiconductor layer 2. The semiconductor recess 14a is formed between the adjacent light-emitting elements 12a. In other words, it is formed to surround the outer periphery of each light-emitting element 12a. The forming method is similar to that of the separation trench formation of S35. In the present configuration, since a portion of the light-emitting element layer 5 is continuously connected between the light-emitting elements 12a, when the light-emitting elements 12a are miniaturized, the optical crosstalk in which light leaks to the adjacent light-emitting element may occur. The present step is intended to reduce the thickness of the semiconductor layer 2 which is connected between the adjacent light-emitting elements, in order to reduce the optical crosstalk. Note that when the optical crosstalk is not a problem, the present step can be omitted.

In S42b illustrated in FIG. 22, similar to the S41 step illustrated in FIG. 20, a protruding pattern serving as the upper portion 11U of the light shielding layer 11 is formed. In the present step, for example, a metal thin film to serve as the upper portion 11U of the light shielding layer 11 is deposited to form the metal thin film into a wall shape by using the photolithography technique and the dry etching technique. Alternatively, the metal thin film may be formed into the wall shape by using the lift-off method. In a plan view, the upper portion 11U of the light shielding layer 11 is disposed on the outer periphery of the light-emitting element 12a, and is connected in a lattice pattern in a case where the light-emitting elements 12a are disposed in an array shape. Thus, in a case where aluminum or silver having high electrical conductivity is used as the upper portion 11U of the light shielding layer 11, the light shielding layer 11 can also be used as the wiring line layer. Forming a metallic protruding pattern in this manner has an advantage that a light shielding layer having excellent reflectivity can be realized by a simple process. There is also an advantage that the light shielding layer and the wiring line can be realized simultaneously. Note that the semiconductor layer 2 need not be connected between the light-emitting elements 12a, and the semiconductor recess 14a may reach the lower portion 11L of the light shielding layer 11.

The wavelength conversion can be performed by disposing the phosphor layer 14R as illustrated in FIG. 7 in a bathtub shape region surrounded by the upper portion 11U of the light shielding layer 11, or a full color display element can be realized by disposing the phosphor layers 14R and 14G and the transparent resin layer 14W illustrated in FIG. 8.

According to the present configuration, by maintaining a semiconductor layer continuously connected between the light-emitting elements, a light source device having less defects can be realized. There is further an advantage that an excellent light source device can be realized by suppressing optical crosstalk by a simple process.

Supplement

### First Aspect

A manufacturing method of a light source device, the manufacturing method including: a step of forming a light-emitting element layer by forming a first semiconductor layer, a light-emitting layer, and a second semiconductor layer in this order from a side with a substrate on a surface, of the substrate, on one side;

a step of forming a separation trench in the light-emitting element layer to form a plurality of island shape light-emitting element layers;
a step of forming a light shielding layer made of a material different from a material of the light-emitting element layer, in at least the separation trench; and
a step of forming a plurality of light-emitting elements each including a corresponding one of the plurality of island shape light-emitting element layers having a height less than a height of the light shielding layer by etching one of the first semiconductor layer or the second semiconductor layer of each of the plurality of island shape light-emitting element layers after the step of forming the light shielding layer in the separation trench.

Second Aspect

The manufacturing method of a light source device according to the first aspect, wherein in the step of forming the light-emitting element layer, the first semiconductor layer, the light-emitting layer, and the second semiconductor layer are formed in this order from a side with a first substrate serving as the substrate on a surface, of the first substrate, on one side,

the manufacturing method further includes
a step of forming a plurality of electrodes each electrically connected to one of the first semiconductor layer or the second semiconductor layer, and
a step of electrically connecting each of the plurality of electrodes to a drive circuit or a wiring line provided on the second substrate, and
in the step of forming the plurality of light-emitting elements performed after the step of forming the light shielding layer in the separation trench, the step of forming the plurality of electrodes, and the step of electrically connecting, another of the first semiconductor layer and the second semiconductor layer of each of the plurality of island shape light-emitting element layers is etched, and a plurality of light-emitting elements provided with the plurality of island shape light-emitting element layers having a height less than the height of the light shielding layer are formed on the second substrate.

Third Aspect

The manufacturing method of a light source device according to the second aspect, wherein

in the step of forming the plurality of electrodes, a plurality of electrodes electrically connected to the second semiconductor layer is formed,
in the step of electrically connecting, the surface, of the first substrate, on the one side and the surface of the second substrate on which the drive circuit or the wiring line is formed are disposed to face each other, and each of the plurality of electrodes is electrically connected to the drive circuit or the wiring line,
the manufacturing method further includes a step of removing the first substrate before the step of forming the plurality of light-emitting elements,
in the step of forming the light shielding layer performed before the step of removing the first substrate, a gap including the separation trench is filled with a material different from the material of the light-emitting element layer to form the light shielding layer, and
in the step of forming the plurality of light-emitting elements, the first semiconductor layer of each of the plurality of island shape light-emitting element layers is etched, and the plurality of light-emitting elements each provided with a corresponding one of the plurality of island shape light-emitting element layers having a height less than the height of the light shielding layer are formed on the second substrate.

Fourth Aspect

The manufacturing method of a light source device according to the third aspect, further comprising at least one of a step of making the heights of the plurality of island shape light-emitting element layers uniform and a step of making the height of the light shielding layer uniform, after the step of removing the first substrate and before the step of forming the plurality of light-emitting elements.

Fifth Aspect

The manufacturing method of a light source device according to the second aspect, wherein

in the step of forming the plurality of electrodes, a plurality of through-holes are formed in the first substrate, and each of a plurality of electrodes electrically connected to the first semiconductor layer is formed in a corresponding one of the plurality of through-holes, and
in the step of electrically connecting, a surface, of the first substrate, on another side and a surface of the second substrate on which the drive circuit or the wiring line is formed are disposed to face each other, and each of the plurality of electrodes formed in the corresponding one of the plurality of through-holes is electrically connected to the drive circuit or the wiring line.

Sixth Aspect

The manufacturing method of a light source device according to any one of the first to fifth aspects, the manufacturing method further comprising an insulating film forming step of forming an insulating film covering at least a portion of each side surface of the plurality of island shape light-emitting element layers, after the step of forming the plurality of island shape light-emitting element layers and before the step of forming the light shielding layer.

Seventh Aspect

The manufacturing method of a light source device according to any one of the first to sixth aspects, the manufacturing method further comprising a light reflective film forming step of forming a light reflective film made of a material capable of reflecting light in the separation trench, after the step of forming the plurality of island shape light-emitting element layers and before the step of forming the light shielding layer.

Eighth Aspect

A light source device comprising:

a base substrate provided with a drive circuit or a wiring line;
a plurality of light-emitting elements each including an electrode electrically connected to the drive circuit or the wiring line, a first semiconductor layer, a light-emitting layer, a second semiconductor layer in this order from a side with the base substrate on a surface of the base substrate;
a separation trench formed in at least the first semiconductor layer, the light-emitting layer, and the second semiconductor layer between the plurality of light-emitting elements; and
a light shielding layer provided in the separation trench to be higher than heights of the plurality of light-emitting elements.

Ninth Aspect

The light source device according to the eighth aspect, wherein a height of the light shielding layer is uniform.

Tenth Aspect

The light source device according to the eighth or ninth aspect, wherein

the light shielding layer includes an upper portion higher than the heights of the plurality of light-emitting elements, a lower portion having a height being a total of a thickness of the electrode, a thickness of the first semiconductor layer, a thickness of the light-emitting layer, and a thickness of a portion of the second semiconductor layer, and an intermediate portion between the upper portion and the lower portion, and
a side surface of the upper portion and a side surface of the intermediate portion are at least a continuous surface.

Eleventh Aspect

The light source device according to any one of the eighth to tenth aspects, wherein the light shielding layer formed farther from the base substrate than the electrode includes a portion covered with a light reflective film.

Twelfth Aspect

The light source device according to any one of the eighth to eleventh aspects, wherein the light shielding layer includes an upper portion higher than the heights of the plurality of light-emitting elements, a lower portion having a height being a total of a thickness of the electrode, a thickness of the first semiconductor layer, a thickness of the light-emitting layer, and a thickness of a portion of the second semiconductor layer, and an intermediate portion between the upper portion and the lower portion,

the lower portion is formed of an insulating material, and
the upper portion and the intermediate portion are formed of a light reflective material or a conductive material.

Thirteenth Aspect

The light source device according to any one of the eighth to eleventh aspects, wherein the light shielding layer includes an upper portion higher than the heights of the plurality of light-emitting elements, a lower portion having a height being a total of a thickness of the electrode, a thickness of the first semiconductor layer, a thickness of the light-emitting layer, and a thickness of a portion of the second semiconductor layer, and an intermediate portion between the upper portion and the lower portion,

the lower portion includes a first portion serving as an insulating layer provided between electrodes each corresponding to the electrode and a second portion that is a remaining portion,
the second portion, the intermediate portion, and the upper portion are formed of a light reflective material or a conductive material, and
an insulating film is formed on a side surface of the second portion.

Fourteenth Aspect

The light source device according to any one of the eighth to thirteenth aspects, wherein exposed surfaces, of the plurality of light-emitting elements and the light shielding layer, on a side opposite to the base substrate are covered with a conductive material.

Fifteenth Aspect

The light source device according to any one of the eighth to fourteenth aspects, wherein exposed surfaces, of the plurality of light-emitting elements and the light shielding layer, on a side opposite to the base substrate are provided with a third semiconductor layer configured to connect together the second semiconductor layers each provided in a corresponding one of the plurality of light-emitting elements.

Sixteenth Aspect

The light source device according to any one of the eighth to fifteenth aspects, wherein a lateral width of the light shielding layer between the plurality of light-emitting elements is narrower as a distance from the base substrate increases.

Seventeenth Aspect

The light source device according to any one of the eighth to sixteenth aspects, wherein a surface, of the second semiconductor layer, on a side with the light-emitting layer is flatter than a surface, of the second semiconductor layer, on a side opposite to the side with the light-emitting layer.

Eighteenth Aspect

A display device including

the light source device according to any one of the eighth to seventeenth aspects, wherein the plurality of light-emitting elements includes a first light-emitting element, a second light-emitting element, and a third light-emitting element disposed adjacent to each other, one pixel includes a first subpixel, a second subpixel, and a third subpixel,
the first subpixel includes the first light-emitting element,
the second subpixel includes the second light-emitting element,
the third subpixel includes the third light-emitting element, and
the first subpixel, the second subpixel, and the third subpixel are subpixels configured to emit light beams having colors different from each other.

Nineteenth Aspect

A manufacturing method of a light source device, the manufacturing method including:

a step of forming a light-emitting element layer by forming a first semiconductor layer, a light-emitting layer, and a second semiconductor layer in this order from a side with a substrate on a surface, of the substrate, on one side;
a step of forming a plurality of island shape light-emitting element layers by forming a separation trench in the light-emitting element layer;
a step of forming a first light shielding layer made of a material different from a material of the light-emitting element layer at least in the separation trench;
a step of etching the first semiconductor layer of each of the plurality of island shape light-emitting element layers; and
a step of forming a protruding pattern serving as a second light shielding layer on the first semiconductor layer.

Twentieth Aspect

The manufacturing method of a light source device according to the nineteenth aspect, wherein the step of etching the first semiconductor layer is performed after the step of forming the protruding pattern serving as the second light shielding layer.

Twenty-first Aspect

The manufacturing method of a light source device according to the nineteenth aspect, wherein the step of etching the first semiconductor layer is performed before the step of forming the protruding pattern serving as the second light shielding layer.

Twenty-second Aspect

A light source device including:

a base substrate provided with a drive circuit or a wiring line;
a plurality of light-emitting elements including an electrode electrically connected to the drive circuit or the wiring line, a first semiconductor layer, a light-emitting layer, and a second semiconductor layer in this order from a side with the base substrate on a surface of the base substrate; and
a separation trench formed in at least a portion of the first semiconductor layer, the light-emitting layer, and the second semiconductor layer between the plurality of light-emitting elements, wherein
the separation trench is filled with a first light shielding layer, and
a second light shielding layer including a protruding pattern provided on a surface, of the first semiconductor layer, on a light-emitting side is included between the plurality of light-emitting elements.

Twenty-third Aspect

The light source device according to the twenty-second aspect, wherein the surface, of the first semiconductor layer of the plurality of light-emitting elements, on the light-emitting side is lower in a portion uncovered with the protruding pattern than in a portion covered with the protruding pattern.

Twenty-fourth Aspect

The light source device according to according to the twenty-second aspect, wherein the surface, of the first semiconductor layer of the plurality of light-emitting elements, on the light-emitting side is higher in a portion uncovered with the protruding pattern than in a portion covered with the protruding pattern.

Twenty-fifth Aspect

The light source device according to any one of the twenty-second to twenty-fourth aspects, wherein the protruding pattern is made of a metal.

### SUPPLEMENTARY INFORMATION

The present disclosure is not limited to each of the above-described embodiments. It is possible to make various modifications within the scope of the claims. An embodiment obtained by appropriately combining technical elements each disclosed in different embodiments falls also within the technical scope of the present disclosure. Furthermore, technical elements disclosed in the respective embodiments may be combined to provide a new technical feature.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A manufacturing method of a light source device, the manufacturing method comprising:
a step of forming a light-emitting element layer by forming a first semiconductor layer, a light-emitting layer, and a second semiconductor layer in this order from a side with a substrate on a surface, of the substrate, on one side;
a step of forming a separation trench in the light-emitting element layer to form a plurality of island shape light-emitting element layers;
a step of forming a light shielding layer made of a material different from a material of the light-emitting element layer, in at least the separation trench; and
a step of forming a plurality of light-emitting elements each including a corresponding one of the plurality of island shape light-emitting element layers having a height less than a height of the light shielding layer by etching one of the first semiconductor layer or the second semiconductor layer of each of the plurality of island shape light-emitting element layers after the step of forming the light shielding layer in the separation trench.

2. The manufacturing method of a light source device according to claim 1,
wherein, in the step of forming the light-emitting element layer, the first semiconductor layer, the light-emitting layer, and the second semiconductor layer are formed in this order from a side with a first substrate serving as the substrate on a surface, of the first substrate, on one side,
the manufacturing method further includes
a step of forming a plurality of electrodes each electrically connected to one of the first semiconductor layer or the second semiconductor layer, and
a step of electrically connecting each of the plurality of electrodes to a drive circuit or a wiring line provided on the second substrate, and
in the step of forming the plurality of light-emitting elements performed after the step of forming the light shielding layer in the separation trench, the step of forming the plurality of electrodes, and the step of electrically connecting, another of the first semiconductor layer and the second semiconductor layer of each of the plurality of island shape light-emitting element layers is etched, and a plurality of light-emitting elements provided with the plurality of island shape light-emitting element layers having a height less than the height of the light shielding layer are formed on the second substrate.

3. The manufacturing method of a light source device according to claim 2,
wherein, in the step of forming the plurality of electrodes, a plurality of electrodes electrically connected to the second semiconductor layer is formed,
in the step of electrically connecting, the surface, of the first substrate, on the one side and the surface of the second substrate on which the drive circuit or the wiring line is formed are disposed to face each other, and each of the plurality of electrodes is electrically connected to the drive circuit or the wiring line,
the manufacturing method further includes a step of removing the first substrate before the step of forming the plurality of light-emitting elements,
in the step of forming the light shielding layer performed before the step of removing the first substrate, a gap including the separation trench is filled with a material different from the material of the light-emitting element layer to form the light shielding layer, and
in the step of forming the plurality of light-emitting elements, the first semiconductor layer of each of the plurality of island shape light-emitting element layers is etched, and the plurality of light-emitting elements each provided with a corresponding one of the plurality of island shape light-emitting element layers having a height less than the height of the light shielding layer are formed on the second substrate.

4. The manufacturing method of a light source device according to claim 3, further comprising:
at least one of a step of making the heights of the plurality of island shape light-emitting element layers uniform and a step of making the height of the light shielding layer uniform, after the step of removing the first substrate and before the step of forming the plurality of light-emitting elements.

5. The manufacturing method of a light source device according to claim 2,
wherein, in the step of forming the plurality of electrodes, a plurality of through-holes are formed in the first substrate, and each of a plurality of electrodes electrically connected to the first semiconductor layer is formed in a corresponding one of the plurality of through-holes, and
in the step of electrically connecting, a surface, of the first substrate, on another side and a surface of the second substrate on which the drive circuit or the wiring line is formed are disposed to face each other, and each of the plurality of electrodes formed in the corresponding one of the plurality of through-holes is electrically connected to the drive circuit or the wiring line.

6. The manufacturing method of a light source device according to claim 1, further comprising:
an insulating film forming step of forming an insulating film covering at least a portion of each side surface of the plurality of island shape light-emitting element layers, after the step of forming the plurality of island shape light-emitting element layers and before the step of forming the light shielding layer.

7. The manufacturing method of a light source device according to claim 1, further comprising:
a light reflective film forming step of forming a light reflective film made of a material capable of reflecting light in the separation trench, after the step of forming the plurality of island shape light-emitting element layers and before the step of forming the light shielding layer.

8. A light source device comprising:
a base substrate provided with a drive circuit or a wiring line;
a plurality of light-emitting elements each including an electrode electrically connected to the drive circuit or the wiring line, a first semiconductor layer, a light-emitting layer, a second semiconductor layer in this order from a side with the base substrate on a surface of the base substrate;
a separation trench formed in at least the first semiconductor layer, the light-emitting layer, and the second semiconductor layer between the plurality of light-emitting elements; and
a light shielding layer provided in the separation trench to be higher than heights of the plurality of light-emitting elements.

9. The light source device according to claim 8,
wherein a height of the light shielding layer is uniform.

10. The light source device according to claim 8,
wherein the light shielding layer includes an upper portion higher than the heights of the plurality of light-emitting elements, a lower portion having a height being a total of a thickness of the electrode, a thickness of the first semiconductor layer, a thickness of the light-emitting layer, and a thickness of a portion of the second semiconductor layer, and an intermediate portion between the upper portion and the lower portion, and
a side surface of the upper portion and a side surface of the intermediate portion are at least a continuous surface.

11. The light source device according to claim 8,
wherein the light shielding layer formed farther from the base substrate than the electrode includes a portion covered with a light reflective film.

12. The light source device according to claim 8,
wherein the light shielding layer includes an upper portion higher than the heights of the plurality of light-emitting elements, a lower portion having a height being a total of a thickness of the electrode, a thickness of the first semiconductor layer, a thickness of the light-emitting layer, and a thickness of a portion of the second semiconductor layer, and an intermediate portion between the upper portion and the lower portion,
the lower portion is formed of an insulating material, and
the upper portion and the intermediate portion are formed of a light reflective material or a conductive material.

13. The light source device according to claim 8,
wherein the light shielding layer includes an upper portion higher than the heights of the plurality of light-emitting elements, a lower portion having a height being a total of a thickness of the electrode, a thickness of the first semiconductor layer, a thickness of the light-emitting layer, and a thickness of a portion of the second semiconductor layer, and an intermediate portion between the upper portion and the lower portion,
the lower portion includes a first portion serving as an insulating layer provided between electrodes each corresponding to the electrode and a second portion that is a remaining portion,
the second portion, the intermediate portion, and the upper portion are formed of a light reflective material or a conductive material, and
an insulating film is formed on a side surface of the second portion.

14. The light source device according to claim 8,
wherein exposed surfaces, of the plurality of light-emitting elements and the light shielding layer, on a side opposite to the base substrate are covered with a conductive material.

15. The light source device according to claim 8,
wherein exposed surfaces, of the plurality of light-emitting elements and the light shielding layer, on a side opposite to the base substrate are provided with a third semiconductor layer configured to connect together the second semiconductor layers each provided in a corresponding one of the plurality of light-emitting elements.

16. The light source device according to claim 8,
wherein a lateral width of the light shielding layer between the plurality of light-emitting elements is narrower as a distance from the base substrate increases.

17. The light source device according to claim 8,
wherein a surface, of the second semiconductor layer, on a side with the light-emitting layer is flatter than a surface, of the second semiconductor layer, on a side opposite to the side with the light-emitting layer.

18. A display device comprising:
the light source device according to claim 8,
wherein the plurality of light-emitting elements includes a first light-emitting element, a second light-emitting element, and a third light-emitting element disposed adjacent to each other,
one pixel includes a first subpixel, a second subpixel, and a third subpixel,
the first subpixel includes the first light-emitting element,
the second subpixel includes the second light-emitting element,
the third subpixel includes the third light-emitting element, and
the first subpixel, the second subpixel, and the third subpixel are subpixels configured to emit light beams having colors different from each other.

19. A manufacturing method of a light source device, the manufacturing method comprising:
a step of forming a light-emitting element layer by forming a first semiconductor layer, a light-emitting layer, and a second semiconductor layer in this order from a side with a substrate on a surface, of the substrate, on one side;
a step of forming a plurality of island shape light-emitting element layers by forming a separation trench in the light-emitting element layer;
a step of forming a first light shielding layer made of a material different from a material of the light-emitting element layer at least in the separation trench;
a step of etching the first semiconductor layer of each of the plurality of island shape light-emitting element layers; and
a step of forming a protruding pattern serving as a second light shielding layer on the first semiconductor layer.

20. The manufacturing method of a light source device according to claim 19,
wherein the step of etching the first semiconductor layer is performed after the step of forming the protruding pattern serving as the second light shielding layer.

21. The manufacturing method of a light source device according to claim 19,
wherein the step of etching the first semiconductor layer is performed before the step of forming the protruding pattern serving as the second light shielding layer.

22. A light source device comprising:
a base substrate provided with a drive circuit or a wiring line;
a plurality of light-emitting elements including an electrode electrically connected to the drive circuit or the wiring line, a first semiconductor layer, a light-emitting layer, and a second semiconductor layer in this order from a side with the base substrate on a surface of the base substrate; and
a separation trench formed in at least a portion of the first semiconductor layer, the light-emitting layer, and the second semiconductor layer between the plurality of light-emitting elements,
wherein the separation trench is filled with a first light shielding layer, and
a second light shielding layer including a protruding pattern provided on a surface, of the first semiconductor layer, on a light-emitting side is included between the plurality of light-emitting elements.

23. The light source device according to claim 22,
wherein the surface, of the first semiconductor layer of the plurality of light-emitting elements, on the light-emitting side is lower in a portion uncovered with the protruding pattern than in a portion covered with the protruding pattern.

24. The light source device according to claim 22,
wherein the surface, of the first semiconductor layer of the plurality of light-emitting elements, on the light-emitting side is higher in a portion uncovered with the protruding pattern than in a portion covered with the protruding pattern.

25. The light source device according to claim 22,
wherein the protruding pattern is made of a metal.
